(19) United States
(12) Patent Application Publication
(10) Pub. No.: US 2016/0186009 A1
(43) Pub. Date: Jun. 30, 2016

(54) GAS BARRIER FILM

(71) Applicant: KONICA MINOLTA, INC., Tokyo (JP)

(72) Inventor: Yoshitaka GOTO, Tokyo (JP)

(21) Appl. No.: 14/908,869

(22) PCT Filed: Aug. 4, 2014
(86) PCT No.: PCT/JP2014/070516

§ 371 Date: Jan. 29, 2016

(30) Foreign Application Priority Data
Aug. 7, 2013 (JP) 2013-164209

(51) Int. Cl. C09D 183/16; C08J 7/04; H01L 51/52; B05D 7/00; B05D 3/06; H01L 51/00; H01L 51/50

(52) U.S. Cl. CPC C09D 183/16; H01L 51/0034; C08J 7/042; H01L 51/5056; H01L 51/0072; H01L 51/0073; H01L 51/0085; B05D 7/58; B05D 3/065; H01L 51/5253; C08J 2483/16; C08J 2367/02; H01L 2251/558

(57) ABSTRACT

[Object] Provided is a gas barrier film that is substantially uniformly modified in the film thickness direction and exhibits excellent interlayer adhesive force and bending resistance even after being stored under a high temperature and high humidity condition.

[Solving Means] Disclosed is a gas barrier film including a plurality of gas barrier layers, the gas barrier film being obtained by coating a coating liquid containing a polysilazane compound on a substrate by simultaneous multilayer coating and drying it to form a plurality of coating layers and then irradiating the plurality of coating layers with vacuum ultraviolet rays from the side of the farthest coating layer from the substrate to conduct a modification treatment, in which at least one layer of the gas barrier layers contains at least one kind of element (however, silicon and carbon are excluded) selected from the group consisting of elements of group 2, group 13, and group 14 in the long form of the periodic table.

### TECHNICAL FIELD

The present invention relates to a gas barrier film.

### BACKGROUND ART

Hitherto, gas barrier films having a relatively simple structure in which an inorganic film such as a deposited film of a metal or a metal oxide is provided on the surface of a resin substrate have been used in the fields such as food, packaging materials, and pharmaceuticals in order to prevent the permeation of gas such as water vapor or oxygen.

In recent years, such gas barrier films to prevent the permeation of water vapor, oxygen, or the like have been also utilized in the field of electronic devices such as a liquid crystal display device (LCD), a photovoltaic (PV) cell, and organic electroluminescence (EL). Not a glass substrate that is hard and easily broken but a gas barrier film exhibiting high gas barrier property is required in order to impart flexibility and the property that is light and hardly broken to such an electronic device.

A method for producing a gas barrier film having a plurality of gas barrier layers is disclosed in Japanese Patent Application Laid-Open (JP-A) No. 2012-599 in which a step of forming a gas barrier layer by forming a coating film on a substrate using a coating liquid containing a polysilazane compound and then subjecting it to a modification treatment of being irradiated with vacuum ultraviolet rays using an excimer lamp or the like is repeated a plurality of times.

In addition, a method for producing a gas barrier film is disclosed in JP 2012-250181 A in which a plurality of coating films are obtained using a coating liquid containing a polysilazane compound and the modification treatment of the plurality of layers is then collectively conducted by irradiating them with vacuum ultraviolet rays using an excimer lamp or the like.

Furthermore, a method for producing a gas barrier film is disclosed in JP 2012-148416 A in which a coating film containing a polysilazane compound is formed on a film that is formed by deposition and then subjected to a modification treatment.

### SUMMARY OF INVENTION

However, in the technology described in JP 2012-599 A, the modification treatment by vacuum ultraviolet ray irradiation is conducted for each gas barrier layer, thus the coating step and the modification treatment are alternately repeated, the step is complicated, and the number of steps also increases. Due to this, there is a problem that contamination of the gas barrier layer with a foreign substance and dirt in the in-process environment frequently occurs, a gas barrier layer having uniform film quality is not obtained, and the gas barrier property greatly decreases.

In addition, in the technology described in JP 2012-250181A, although the uppermost layer and the layer that is present in the vicinity thereof are uniformly modified to some extent by increasing the irradiation energy of vacuum ultraviolet rays, there is a problem that uniform modification did not occur in the film thickness direction as the number of layers increases, a stacked film which does not have interlayer adhesive force is obtained, and as a result, the gas barrier property decreases as a whole. In addition, there is a problem that the physical properties such as bending resistance and interlayer adhesive force decrease as the gas barrier layer is not uniformly modified.

Furthermore, in the technology described in JP 2012-148416 A, there is a problem that the stability or adhesive force of the gas barrier layer is insufficient after storage in a severe environment, and a significant deterioration in film quality or interlayer adhesive force is caused and the gas barrier property is insufficient after storage in a high temperature and high humidity environment because the unmodified part of the polysilazane compound remains.

As described above, in the gas barrier film having a plurality of gas barrier layers, a technology in which a uniform modification treatment is performed in the film thickness direction, and the adhesive force between the respective gas barrier layers or bending resistance does not deteriorate even after storage under a high temperature and high humidity condition is desired.

The present invention has been made in view of the above circumstance, and an object thereof is to provide a gas barrier film that is substantially uniformly modified in the film thickness direction and exhibits excellent interlayer adhesive force and bending resistance even after being stored under a high temperature and high humidity condition, a method for producing the gas barrier film, and an electronic device including the gas barrier film.

The above object of the present invention is achieved by the following means.

1. A gas barrier film including a plurality of gas barrier layers, the gas barrier film being obtained by coating a coating liquid containing a polysilazane compound on a substrate by simultaneous multilayer coating and drying it to form a plurality of coating layers and then irradiating the plurality of coating layers with vacuum ultraviolet rays from the side of the farthest coating layer from the substrate to conduct a modification treatment and in which at least one layer of the gas barrier layers contains at least one kind of element (however, silicon and carbon are excluded) selected from the group consisting of elements of group 2, group 13, and group 14 in the long form of the periodic table.

2. The gas barrier film according to 1 above, in which at least one kind of element selected from the group consisting of elements of group 2, group 13, and group 14 in the long form of the periodic table is at least one kind selected from the group consisting of aluminum, indium, gallium, magnesium, calcium, germanium, and boron.

3. The gas barrier film according to 1 or 2 above, in which a thickness of the substrate is from 10 to 100 μm.

4. The gas barrier film according to any one of 1 to 3 above, wherein the gas barrier film is formed by further conducting a temperature treatment after the modification treatment.

5. A method for producing a gas barrier film including a plurality of gas barrier layers, the method including: a step of forming a plurality of coating layers by coating a coating liquid containing a polysilazane compound on a substrate by simultaneous multilayer coating and drying it; and a step of conducting a modification treatment by irradiating the plurality of coating layers with vacuum ultraviolet rays from the side of the farthest coating layer from the substrate, in which at least one layer of the coating layers contains at least one kind of element (however, silicon and carbon are excluded) selected from the group consisting of elements of group 2, group 13, and group 14 in the long form of the periodic table.

6. An electronic device including an electronic device body and the gas barrier film according to any one of 1 to 4 above or a gas barrier film obtained by the producing method according to 5 above.

### BRIEF DESCRIPTION OF DRAWINGS

FIG. 1 is a schematic diagram illustrating an example of an atmospheric pressure plasma discharge treatment apparatus that has a system to treat a substrate in the space between counter electrodes and is useful when forming a deposited gas barrier layer according to the present invention, in which 30 is a plasma discharge treatment apparatus, 31 is a plasma discharge treatment vessel, 32 is space between counter electrodes (electric discharge space), 35 is a roll rotating electrode (first electrode), 36 is a square tube type fixed electrode (second electrode), 40 is an electric field applying means having two power supplies, 41 is a first power supply, 42 is a second power supply, 43 is a first filter, 44 is a second filter, 50 is a gas supply means, 51 is a gas generator, 53 is an exhaust port, 60 is an electrode temperature controlling means, 61 is a pipe, 64 and 67 are guide rolls, 65 and 66 are nip rolls, 68 and 69 are partition plates, F is a substrate, P is a liquid feeding pump, G is a gas, and G′ is a treated exhaust gas subjected to the electric discharge treatment.

FIG. 2 is a schematic sectional diagram illustrating an example of a vacuum ultraviolet ray irradiating apparatus, in which 11 is an apparatus chamber, 12 is an Xe excimer lamp, 13 is a holder for the excimer lamp which also serves as an external electrode, 14 is a sample stage, 15 is a sample on which a layer is formed, and 16 is a light shielding plate.

### DETAILED DESCRIPTION

According to the present invention, a gas barrier film includes a plurality of gas barrier layers, the gas barrier film being obtained by coating a coating liquid containing a polysilazane compound (hereinafter, also simply referred to as the polysilazane) on a substrate by simultaneous multilayer coating and drying it to form a plurality of coating layers and then irradiating the plurality of coating layers with vacuum ultraviolet rays from the side of the farthest coating layer from the substrate to conduct a modification treatment, in which at least one layer of the gas barrier layers contains at least one kind of element (however, silicon and carbon are excluded) (hereinafter, also simply referred to as the addictive element)selected from the group consisting of elements of group 2, group 13, and group 14 in the long form of the periodic table.

A gas barrier film that is substantially uniformly modified in the film thickness direction and exhibits excellent interlayer adhesive force and bending resistance even after being stored under a high temperature and high humidity condition is obtained by having such a configuration.

It is believed that the effect in the gas barrier film of the present invention is exerted by the following reason although the detailed mechanism thereof is unknown.

In the method for producing a gas barrier film of the prior art in which a gas barrier layer is formed by coating and drying a coating liquid containing a polysilazane to obtain a coating layer and then irradiating the coating layer with vacuum ultraviolet rays using an excimer lamp or the like to conduct a modification treatment, the modification proceeds from the surface of the coating layer, and thus oxygen or moisture does not enter the inside of the coating layer and oxidation hardly proceeds up to the inside of the coating layer or the interface between the coating layer and the substrate. Hence, there is a problem that the unmodified coating layer remains as it is unstable and the performance such as gas barrier property deteriorates particularly after storage at a high temperature and a high humidity. It has been attempted to conduct the modification by increasing the irradiation quantity of vacuum ultraviolet rays as in the technology described in JP 2012-250181 A, but there is also a problem that a dangling bond is formed on the surface of the coating layer as it is exposed to vacuum ultraviolet rays, the quantity of vacuum ultraviolet rays absorbed by the surface increases, and the efficiency of modification worsens, and there is a problem that it is extremely difficult to conduct the modification treatment of a plurality of coating layers at a time.

In a layer that is formed by coating and drying a coating liquid containing a polysilazane but does not contain at least one kind of element (hereinafter, also simply referred to as the addictive element) selected from the group consisting of elements of group 2, group 13, and group 14, the absorbance at 250 nm or less increases perhaps since the dangling bond increases as described above as the layer is irradiated with an energy ray as the modification treatment, the energy ray is gradually less likely to penetrate up to the inside of the layer, and only the surface of the layer is modified. On the other hand, the absorbance on the low wavelength side decreases as the layer is irradiated with an energy ray when an additive element is contained although the reason is not clear. Hence, it has been found that when at least one coating layer among the plurality of coating layers contains an additive element, by irradiating the coating layers with vacuum ultraviolet rays from the side of the farthest coating layer from the substrate, the modification uniformly proceeds from the surface to the inside of the farthest coating layer from the substrate and a layer below the layer in the same manner, and the modification proceeds in a layer further below the layer and a layer even further below the layer so that the modification uniformly proceeds in the film thickness direction, and as a result, it has been found out for the first time that a surprising phenomenon that the modification of all the layers proceeds by one time of vacuum ultraviolet ray irradiation occurs.

Accordingly, when forming a plurality of gas barrier layers, the process is simplified since a complicated operation of alternately conducting the steps of the coating step and the modification treatment step is not required as in JP 2012-599 A, and thus a foreign substance or dust to contaminate the film in the in-process environment significantly decreases. In addition, as the film quality is uniform in the film thickness direction, the adhesive force between the plurality of gas barrier layers is also significantly improved, and the positions at which the stress is locally concentrated in the inside of the gas barrier layer or between the gas barrier layers significantly decrease. Consequently, a gas barrier film is obtained which is hardly cracked, exhibits excellent interlayer adhesive force and bending resistance, and is hardly deteriorated in gas barrier property even after being store under a high temperature and high humidity condition.

In addition, recently, further weight saving and thinning of the gas barrier film are also desired along with the weight saving or thinning of the electronic device, and as a means to cope with such a requirement, the thinning of the substrate of the gas barrier film is mentioned. However, in the case of thinning the substrate, there is a possibility that curling of the film due to coating and drying or thermal deterioration of the substrate due to repeated thermal history occurs in the prior art. According to the present invention, a plurality of coating layers can be obtained by only conducting the coating step and the drying step one time, thus it is possible to suppress curling of the film, the thermal deterioration of the substrate, or the like although the substrate is thinned, and it is possible to obtain a gas barrier film which exhibits excellent gas barrier property, and excellent interlayer adhesive force and bending resistance after being stored under a high temperature and high humidity condition. Consequently, the gas barrier film of the present invention can contribute to the weight saving or thinning of an electronic device.

Incidentally, the above mechanism is a mechanism according to a presumption, and thus the present invention is not only limited to the above mechanism in any way.

Hereinafter, preferred embodiments of the present invention will be described. Incidentally, the present invention is not limited to the following embodiments.

In addition, in the present specification, the expression “X to Y” which denotes the range means “X or more and Y or less”, and the terms “weight” and “mass”, “% by weight” and “% by mass”, and “parts by weight” and “parts by mass” are used as synonyms. In addition, the operation and the measurement of physical properties and the like are conducted under the condition of room temperature (20 to 25° C.)/relative humidity of 40 to 50% RH unless otherwise specified.

[Gas Barrier Film]

The gas barrier film of the present invention includes a substrate and a plurality of gas barrier layers. The gas barrier film of the present invention may further include other members. The gas barrier film of the present invention may include other members, for example, between the substrate and any one of the gas barrier layers, on any one of the gas barrier layers, or on the other surface on which the gas barrier layer is not formed of the substrate. Here, other members are not particularly limited, and a member that is used in a gas barrier film of the prior art can be used in the same manner or after being appropriately modified. Specific examples thereof may include a gas barrier layer formed by a deposition method, a smoothing layer, an anchor coat layer, a bleed-out preventing layer, an intermediate layer, a protective layer, and a functional layer such as a desiccant layer (moisture absorbing layer), or an antistatic layer. The other members may be used singly or in combination of two or more kinds thereof. In addition, the above other members may be present as a single layer or may have a layered structure of two or more layers.

Moreover, in the present invention, the plurality of gas barrier layers may be formed at least on the same one surface of the substrate. Hence, the gas barrier film of the present invention includes both of a form in which the plurality of gas barrier layers are formed on one surface of the substrate and a form in which the plurality of gas barrier layers are formed on both surfaces of the substrate.

[Substrate]

The substrate of the gas barrier film according to the present invention is not particularly limited as long as it can hold the gas barrier layer.

Examples thereof may include various resin films such as a poly(meth)acrylic acid ester, polyethylene terephthalate (PET), polybutylene terephthalate, polyethylene naphthalate (PEN), polycarbonate (PC), polyarylate, polyvinyl chloride (PVC), polyethylene (PE), polypropylene (PP), polystyrene (PS), nylon (Ny), an aromatic polyamide, polyether ether ketone, a polysulfone, a polyether sulfone, a polyimide, a polyether imide, a cycloolefin polymer, and a cycloolefin copolymer, a heat resistant and transparent film containing silsesquioxane having an organic and inorganic hybrid structure as a basic scaffold (product name: Sila-DEC, manufactured by CHISSO CORPORATION), and further a resin film formed by stacking the above resins two or more layers. Polyethylene terephthalate (PET), polybutylene terephthalate, and polyethylene naphthalate (PEN) are preferably used from the viewpoint of cost or ease of availability, and a cycloolefin polymer, a cycloolefin copolymer, and polycarbonate (PC) are preferable from the viewpoint of low retardation. Moreover, it is possible to preferably use a heat resistant and transparent film containing silsesquioxane having an organic and inorganic hybrid structure as a basic scaffold from the viewpoint of optical transparency, heat resistance, and adhesive property with the gas barrier layer. In addition, it is also preferable to use a polyimide and the like as a heat resistant substrate. This is because the use of a heat resistant substrate (ex. Tg>200° C.) makes it possible to heat at a temperature of 200° C. or higher in the device fabricating process, and thus it is possible to achieve a decrease in resistance of the transparent conductive layer or the pattern layer by a metal nano-particles that is required for an increase in area of the device or an increase in operation efficiency of the device. In other words, it is possible to greatly improve the initial properties of the device.

The thickness of the substrate is not particularly limited, but it is preferably from 5 to 300 μm and more preferably from 10 to 100 μm. In this manner, it is possible to use a thinner substrate as compared to those used in the prior art as the substrate according to the present invention, and this can contribute to weight saving and thinning of the electronic device. The substrate may have a functional layer such as a transparent conductive layer, a primer layer, and a clear hard coat layer. As the functional layer, it is possible to preferably adopt those described in the paragraphs of “0036” to “0038” of JP 2006-289627 A in addition to those described above.

In addition, the substrate according to the present invention is preferably transparent. This is because it is possible to obtain a transparent gas barrier film as the substrate is transparent and the layer to be formed on the substrate is also transparent, and thus it is possible to use the transparent gas barrier film as a transparent substrate of an organic EL device and the like.

The substrate is preferably those which have a surface exhibiting high smoothness. As the smoothness of the surface, it is preferable that the average surface roughness (Ra) is 2 nm or less. The lower limit is not particularly limited, but it is practically 0.01 nm or more. If necessary, the smoothness may be improved by polishing both surfaces of the substrate or at least the surface provided with the gas barrier layer.

In addition, the substrates using the resin mentioned above and the like may be a non-stretched film or a stretched film.

The substrate used in the present invention can be produced by a general method known in the prior art. For example, it is possible to produce a substrate that is substantially amorphous, not aligned, and not stretched by melting a resin of the material using an extruder, extruding the melted resin using a circular die or a T-die, and quenching the extruded resin. In addition, it is possible to produce a stretched substrate by stretching the unstretched substrate in the flow (vertical axis) direction of the substrate or the direction perpendicular (horizontal axis) to the flow direction of the substrate by a known method such as uniaxial stretching, tenter type sequential biaxial stretching, tenter type simultaneous biaxial stretching, or tubular type simultaneous biaxial stretching. The stretching ratio in this case can be appropriately selected depending on the resin to be the raw material of the substrate, but it is preferably from 2 to 10 times in the vertical axis direction and the horizontal axis direction, respectively.

At least the side provided with the gas barrier layer according to the present invention of the substrate may be subjected to various known treatments for improving adhesive property, for example, a corona discharge treatment, a flame treatment, an oxidation treatment, or a plasma treatment, stacking of the smoothing layer to be described later, and the like may be conducted, and it is preferable to conduct the above treatments in combination if necessary.

[Gas Barrier Layer]

The gas barrier film of the present invention includes a plurality (two or more layers) of gas barrier layers on a substrate. The plurality of gas barrier layers are obtained by coating a coating liquid containing a polysilazane compound on a substrate by simultaneous multilayer coating and drying it to form a plurality of coating layers and then irradiating the coating layers with vacuum ultraviolet rays from the side of the farthest coating layer from the substrate to conduct a modification treatment. Meanwhile, at least one layer of the gas barrier layers contains an additive element.

The number of the gas barrier layers is not particularly limited as long as it is two or more layers, but it is preferably from 3 to 10 layers and more preferably from 3 to 6 layers from the viewpoint of gas barrier property.

The position of the gas barrier layer containing an additive element in the stacking direction is not particularly limited, but the gas barrier layer containing an additive element is preferably present at a position farther from the substrate and even more preferably present as the farthest outermost layer from the substrate. In this form, the coating layer containing an additive element before being subjected to the modification treatment is present as the outermost layer, and thus the modification of the layers below the outermost layer proceeds in the same manner as the gas barrier film is irradiated with vacuum ultraviolet rays from the side of the outermost layer. Consequently, the gas barrier film is substantially uniformly modified in the film thickness direction, and thus it exhibits excellent interlayer adhesive force and bending resistance even after being stored under a high temperature and high humidity condition.

Amore preferred form is a form in which a gas barrier layer containing an additive element and a gas barrier layer which does not contain an additive element are alternately stacked. In this form, the uniformity of modification in the film thickness direction is further improved, and thus a gas barrier film which exhibits further improved interlayer adhesive force or bending resistance even after being stored under a high temperature and high humidity condition is obtained. An even more preferred form is a form in which a gas barrier layer containing an additive element is present as the farthest outermost layer from the substrate and a gas barrier layer containing an additive element and a gas barrier layer which does not contain an additive element are alternately stacked.

In the case of including two or more layers of a gas barrier layer containing an additive element, the respective gas barrier layers containing an additive element may have the same composition or different compositions.

The gas barrier layer which does not contain an additive element is formed by subjecting the coating layer which does not contain an additive element to the modification treatment by vacuum ultraviolet ray irradiation. The gas barrier layer containing an additive element is formed by subjecting the coating layer containing a compound containing an additive element (hereinafter, also simply referred to as the additive compound) to the modification treatment by vacuum ultraviolet ray irradiation.

Examples of the additive element may include beryllium (Be), magnesium (Mg), calcium (Ca), strontium (Sr), barium (Ba), radium (Ra), boron(B), aluminum(Al), gallium (Ga), indium (In), thallium (Tl), germanium(Ge), tin (Sn), and lead (Pb). Among these, at least one kind selected from the group consisting of aluminum, indium, gallium, magnesium, calcium, germanium, and boron is preferable from the viewpoint of gas barrier property or adhesive property between the gas barrier layers formed. These additive elements may be single or a combination of two or more kinds thereof.

The content of the additive element in the gas barrier film of the present invention is preferably from 0.001 to 50% by mass and more preferably from 0.1 to 40% by mass with respect to the mass of the total gas barrier layers. Incidentally, in a case in which the gas barrier film of the present invention includes two or more layers of the gas barrier layer containing an additive element, the sum of the contents of the additive elements in the respective layers is adopted as the content of the additive element in the gas barrier film.

Hereinafter, the polysilazane compound and the additive compound that are contained in the coating liquid used in the formation of the coating layer will be described.

<Polysilazane Compound>

A polysilazane is a polymer having a silicon-nitrogen bond and is a ceramic precursor inorganic polymer such as SiO₂, Si₃N₄, and an intermediate solid solution of both of them, SiOₓN_{y}, having a bond such as Si—N, Si—H, and N—H.

Specifically, a polysilazane preferably has the following structure.

[Chem. 1]

[Si(R₁)(R₂)—N(R₃)]ₙ— Formula (I)

In Formula (I) above, R₁, R₂, and R₃ are each independently a hydrogen atom, or an alkyl group, an aryl group, a vinyl group, or a (trialkoxysilyl)alkyl group that is substituted or unsubstituted. At this time, R₁, R₂, and R₃ may be those which are the same as or different from one another. Here, examples of the alkyl group may include a linear, branched, or cyclic alkyl group having from 1 to 8 carbon atoms. More specific examples thereof may include a methyl group, an ethyl group, a n-propyl group, an isopropyl group, a n-butyl group, an isobutyl group, a sec-butyl group, a tert-butyl group, a n-pentyl group, an isopentyl group, a neopentyl group, a n-hexyl group, a n-heptyl group, a n-octyl, a 2-ethylhexyl group, a cyclopropyl group, a cyclopentyl group, and a cyclohexyl group. In addition, examples of the aryl group may include an aryl group having from 6 to 30 carbon atoms. More specific examples thereof may include a non-condensed hydrocarbon group such as a phenyl group, a biphenyl group, or a terphenyl group; and a condensed polycyclic hydrocarbon group such as a pentalenyl group, an indenyl group, a naphthyl group, an azulenyl group, a heptalenyl group, a biphenylenyl group, a fluorenyl group, an acenaphthylenyl group, a pleiadenyl group, an acenaphthenyl group, a phenalenyl group, a phenanthryl group, an anthryl group, a fluoranthenyl group, an acephenanthrylenyl group, an aceanthrylenyl group, a triphenylenyl group, a pyrenyl group, a chrysenyl group, or a naphthacenyl group. Examples of the (trialkoxysilyl)alkyl group may include an alkyl group having from 1 to 8 carbon atoms and a silyl group substituted with an alkoxy group having from 1 to 8 carbon atoms. More specific examples thereof may include 3-(triethoxysilyl)propyl group and a 3-(trimethoxysilyl)propyl group. The substituent that is optionally present in R₁ to R₃ above is not particularly limited, but example thereof may include an alkyl group, a halogen atom, a hydroxyl group (—OH), a mercapto group (—SH), a cyano group (—CN), a sulfo group (—SO₃H), a carboxyl group (—COOH), and a nitro group (—NO₂). Incidentally, the substituent that is optionally present is not the same as R₁ to R₃ to be substituted. For example, R₁ to R₃ are not further substituted with an alkyl group in a case in which R₁ to R₃ are an alkyl group. Among these, R₁, R₂ and R₃ are preferably a hydrogen atom, a methyl group, an ethyl group, a propyl group, an isopropyl group, a butyl group, an isobutyl group, a tert-butyl group, a phenyl group, a vinyl group, a 3-(triethoxysilyl)propyl group, or a 3-(trimethoxysilyl)propyl group.

In addition, in Formula (I) above, n is an integer, and it is preferably determined so that the polysilazane having the structure represented by Formula (I) has a number average molecular weight of from 150 to 150,000 g/mol.

One of the preferred forms of the compound having the structure represented by Formula (I) above is perhydropolysilazane (PHPS) in which R₁, R₂ and R₃ are all a hydrogen atom.

Alternatively, the polysilazane preferably has a structure represented by the following Formula (II).

[Chem. 2]

[Si(R_{1′})(R_{2′})—N(R_{3′})]_{n′}—[Si(R_{4′}(R_{5′})—N(R_{6′})]ₚ— Formula (II)

In Formula (II) above, R_{1′}, R_{2′}, R_{3′}, R_{5′}, and R_{6′} are each independently a hydrogen atom, or an alkyl group, an aryl group, a vinyl group, or a (trialkoxysilyl)alkyl group that is substituted or unsubstituted. At this time, R_{1′}, R_{2′}, R_{3′}, R_{4′}, R_{5′}, and R_{6′} may be those which are the same as or different from one another. In the above, the alkyl group, the aryl group, the vinyl group, or the (trialkoxysilyl)alkyl group that is substituted or unsubstituted has the same definition as that in Formula (I) above, and thus the description thereon will be omitted.

In addition, in Formula (II) above, n′ and p are an integer, and they are preferably determined so that the polysilazane having the structure represented by Formula (II) has a number average molecular weight of from 150 to 150,000 g/mol. Incidentally, n′ and p may be the same as or different from each other.

Among the polysilazanes of Formula (II) above, a compound in which R_{1′}, R_{3′}, and R_{6′} each represent a hydrogen atom and R_{2′}, R_{4′}, and R_{5′} each represent a methyl group; a compound in which R_{1′}, R_{3′}, and R_{6′} each represent a hydrogen atom, R_{2′} and R_{4′} each represent a methyl group, and R_{5′} represents a vinyl group; and a compound in which R_{1′}, R_{3′}, R_{4′}, and R_{6′} each represent a hydrogen atom and R_{2′} and R_{5′} each represent a methyl group are preferable.

Alternatively, the polysilazane preferably has a structure represented by the following Formula (III).

[Chem. 3]

[Si(R_{1″})(R_{2″})—N(R_{3″})]_{n″}—[Si(R_{4″})(R_{5″})—N(R_{6″})]_{p″}—[Si(R_{7″})(R_{8″})—N(R_{9″})]_{q}— Formula (III)

In Formula (III) above, R_{1″}, R_{2″}, R_{3″}, R_{4″}, R_{5″}, R_{6″}, R_{7″}, R_{8″}, and R_{9″} are each independently a hydrogen atom, or an alkyl group, an aryl group, a vinyl group, or a (trialkoxysilyl)alkyl group that is substituted or unsubstituted. At this time, R_{1″}, R_{2″}, R_{3″}, R_{4″}, R_{5″}, R_{6″}, R_{7″}, R_{8″}, and R_{9″} may be those which are the same as or different from one another. In the above, the alkyl group, the aryl group, the vinyl group, or the (trialkoxysilyl)alkyl group that is substituted or unsubstituted has the same definition as that in Formula (I) above, and thus the description thereon will be omitted.

In addition, in Formula (III) above, n″, p″, and q are an integer, and they are preferably determined so that the polysilazane having the structure represented by Formula (III) has a number average molecular weight of from 150 to 150,000 g/mol. Incidentally, n″, p″, and q may be the same as or different from one another.

Among the polysilazanes of Formula (III) above, a compound in which R_{1″}, R_{3″}, and R_{6″}, each represent a hydrogen atom, R_{2″}, R_{4″}, R_{5″}, and R_{8″} each represent a methyl group, R_{9″} represents a (triethoxysilyl) propyl group, and R_{7″} represents an alkyl group or a hydrogen atom is preferable.

Meanwhile, an organopolysilazane obtained by substituting some of the hydrogen atom moieties that are bonded to Si of the polysilazane with an alkyl group and the like has an advantage that the adhesive property with the substrate of a base is improved as it has an alkyl group such as a methyl group, and it is possible to impart toughness to the ceramic film made of a hard and brittle polysilazane, and thus there is an advantage that cracking is suppressed even in the case of further thickening the (average) film thickness. Hence, it is also possible to appropriately select these perhydropolysilazane and organopolysilazane depending on the application and to use them by mixing together.

It is presumed that perhydropolysilazane has a structure in which a linear structure and a ring structure mainly consisting of a 6-membered ring and/or an 8-membered ring are present together. The molecular weight thereof is about from 600 to 2000 (in terms of polystyrene) as the number average molecular weight (Mn), there is a case that it is a liquid or solid substance, and the state thereof varies depending on the molecular weight.

These polysilazanes are commercially available in a state of a solution dissolved in an organic solvent, and a commercially available product can be used as a coating liquid for forming a gas barrier layer which does not contain an additive element as it is. Examples of the commercially available product of the polysilazane solution may include NN120-10, NN120-20, NAX120-20, NN110, NN310, NN320, NL110A, NL120A, NL120-20, NL150A, NP110, NP140, and SP140 manufactured by AZ Electronic Materials Co., Ltd.

Although it is not limited to the following ones, other examples of the polysilazane which can be used in the present invention may include a polysilazane that is formed into ceramic at a low temperature such as a silicon alkoxide-added polysilazane that is obtained by reacting polysilazane with the a silicon alkoxide (JP 5-238827 A), a glycidol-added polysilazane obtained by reacting with glycidol (JP 6-122852 A), an alcohol-added polysilazane obtained by reacting with an alcohol (JP 6-240208 A), a metal carboxylate-added polysilazane obtained by reacting with a metal carboxylate salt (JP 6-299118 A), an acetylacetonate complex-added polysilazane obtained by reacting with an acetylacetonate complex containing a metal (JP 6-306329A), or a fine metal particle-added polysilazane obtained by adding fine metal particles (JP 7-196986 A).

The content of the polysilazane in the coating layer before being subjected to the modification treatment can be 100% by mass when the entire mass of the coating layer is 100% by mass. In addition, in a case in which the coating layer contains substances other than the polysilazane, the content of the polysilazane in the coating layer is preferably 10% by mass or more and 99% by mass or less, more preferably 40% by mass or more and 95% by mass or less, and even more preferably 70% by mass or more and 95% by mass or less.

It is possible to contain an inorganic precursor compound in the coating liquid containing a polysilazane other than the polysilazane. The kind of the inorganic precursor compound other than the polysilazane compound is not particularly limited as long as it is possible to prepare a coating liquid.

Specific examples thereof may include a silicon compound such as polysiloxane, polysilsesquioxane, tetramethylsilane, trimethylmethoxysilane, dimethyldimethoxysilane, methyltrimethoxysilane, trimethylethoxysilane, dimethyldiethoxysilane, methyltriethoxysilane, tetramethoxysilane, tetramethoxysilane, hexamethyldisiloxane, hexamethyldisilazane, 1,1-dimethyl-1-silacyclobutane, trimethylvinylsilane, methoxydimethylvinylsilane, trimethoxyvinylsilane, ethyltrimethoxysilane, dimethyldivinylsilane, dimethylethoxyethynylsilane, diacetoxydimethylsilane, dimethoxymethyl-3,3,3-trifluoropropylsilane, 3,3,3-trifluoropropyltrimethoxysilane, aryltrimethoxysilane, ethoxydimethylvinylsilane, arylaminotrimethoxysilane, N-methyl-N-trimethylsilylacetamide, 3-aminopropyltrimethoxysilane, methyltrivinylsilane, diacetoxymethylvinylsilane, methyltriacetoxysilane, aryloxydimethylvinylsilane, diethylvinylsilane, butyltrimethoxysilane, 3-aminopropyldimethylethoxysilane, tetravinylsilane, triacetoxyvinylsilane, tetraacetoxysilane, 3-trifluoroacetoxypropyltrimethoxysilane, diaryldimethoxysilane, butyldimethoxyvinylsilane, trimethyl-3-vinylthiopropylsilane, phenyltrimethylsilane, dimethoxymethylphenylsilane, phenyltrimethoxysilane, 3-acryloxypropyldimethoxymethylsilane, 3-acryloxypropyltrimethoxysilane, dimethylisopentyloxyvinylsilane, 2-aryloxyethylthiomethoxytrimethylsilane, 3-glycidoxypropyltrimethoxysilane, 3-arylaminopropyltrimethoxysilane, hexyltrimethoxysilane, heptadecafluorodecyltrimethoxysilane, dimethylethoxyphenylsilane, benzoyloxytrimethylsilane, 3-methacryloxypropyldimethoxymethylsilane, 3-methacryloxypropyltrimethoxysilane, 3-isocyanatepropyltriethoxysilane, dimethylethoxy-3-glycidoxypropylsilane, dibutoxydimethylsilane, 3-butylaminopropyltrimethylsilane, 3-dimethylaminopropyldiethoxymethylsilane, 2-(2-aminoethylthioethyl)triethoxysilane, bis(butylamino)dimethylsilane, di-vinylmethylphenylsilane, diacetoxymethylphenylsilane, dimethyl-p-tolylvinylsilane, p-styryltrimethoxysilane, diethylmethylphenylsilane, benzyldimethylethoxysilane, diethoxymethylphenylsilane, decylmethyldimethoxysilane, diethoxy-3-glycidoxypropylmethylsilane, octyloxytrimethylsilane, phenyltrivinylsilane, tetraaryloxysilane, dodecyltrimethylsilane, diarylmethylphenylsilane, diphenylmethylvinylsilane, diphenylethoxymethylsilane, diacetoxydiphenylsilane, dibenzyldimethylsilane, diaryldiphenylsilane, octadecyltrimethylsilane, methyloctadecyldimethylsilane, dococylmethyldimethylsilane, 1,3-divinyl-1,1,3,3-tetramethyldisiloxane, 1,3-divinyl-1,1,3,3-tetramethyldisilazane, 1,4-bis(dimethylvinylsilyl)benzene, 1,3-bis(3-acetoxypropyl)tetramethyldisiloxane, 1,3,5-trimethyl-1,3,5-trivinylcyclotrisiloxane, 1,3,5-tris(3,3,3-trifluoropropyl)-1,3,5-trimethylcyclotrisiloxane, octamethylcyclotetrasiloxane, 1,3,5,7-tetraethoxy-1,3,5, 7-tetramethylcyclotetrasiloxane, or decamethylcyclopentasiloxane.

As the polysiloxane, those which have highly reactive Si—H are preferable and methyl hydrogen polysiloxane is preferable. Examples of methyl hydrogen polysiloxane may include TSF484 manufactured by Momentive Performance Materials Inc.

As the polysilsesquioxane, it is possible to preferably use those which have any of a cage-shaped structure, a ladder-shaped structure, and a random structure. Examples of the cage-shaped polysilsesquioxane may include octakis(tetramethylammonium)pentacyclo-octasiloxane-octakis(yloxide)hydrate; octa(tetramethylammonium)silsesquioxane, octakis(dimethylsiloxy)octasilsesquioxane, octa[[3-[(3-ethyl-3-oxetanyl)methoxy]propyl]dimethylsiloxy]octasilsesquioxane; octaallyloxetanesilsesquioxane, octa[(3-propylglycidylether)dimethylsiloxy]silsesquioxane; octakis[[3-(2,3-epoxypropoxy)propyl]dimethylsiloxy] octasilsesquioxane, octakis[[2-(3,4-epoxycyclohexyl)ethyl]dimethylsiloxy] octasilsesquioxane, octakis[2-(vinyl)dimethylsiloxy]silsesquioxane; octakis(dimethylvinylsiloxy)octasilsesquioxane, octakis [(3-hydroxypropyl)dimethylsiloxy] octasilsesquioxane, octa[(methacryloylpropyl)dimethylsilyloxy]silsesquioxane, and octakis[(3-methacryloxypropyl)dimethylsiloxy]octasilsesquioxane of the Q8 series manufactured by Mayaterials Inc. Examples of the polysilsesquioxane in which a cage-shaped structure, a ladder-shaped structure, and a random structure are believed to be present in a mixed form may include the SR-20, SR-21, and SR-23 of polyphenylsilsesquioxane, the SR-13 of polymethylsilsesquioxane, and the SR-33 of polymethylphenylsilsesquioxane manufactured by KONISHI CHEMICAL IND CO., LTD. In addition, it is also possible to preferably use the Fox series that is manufactured by Dow Corning Toray Co., Ltd., is a polyhydrogensilsesquioxane solution, and is commercially available as a spin-on-glass material.

Among the compounds mentioned above, an inorganic silicon compound that is solid at room temperature is preferable and a hydrogenated silsesquioxane is more preferably used.

<Additive Compound>

In the case of forming a gas barrier layer containing an additive element, a coating layer may be formed by coating and drying a coating liquid prepared by adding an additive compound and then subjected to a modification treatment. Examples of the additive compound may include a metal alkoxide compound containing an additive element.

Specific examples of the metal alkoxide compound may include beryllium acetylacetonate, trimethyl borate, triethyl borate, tri-n-propyl borate, triisopropyl borate, tri-n-butyl borate, tri-tert-butyl borate, magnesium ethoxide, magnesium ethoxyethoxide, magnesium methoxyethoxide, magnesium acetylacetonate, aluminum trimethoxide, aluminum triethoxide, aluminum tri-n-propoxide, aluminum tri-isopropoxide, aluminum tri-n-butoxide, aluminum tri-sec-butoxide, aluminum tri-tert-butoxide, aluminum acetylacetonate, acetoalkoxyaluminum diisopropylate, aluminum ethylacetoacetate diisopropylate, aluminum ethylacetoacetate di-n-butyrate, aluminum diethylacetoacetate mono-n-butyrate, aluminum diisopropylate mono-sec-butyrate, tris(acetylacetonato) aluminum, tris(ethylacetoacetato) aluminum, bis(ethylacetoacetato) (2,4-pentanedionato) aluminum, aluminum alkylacetoacetate diisopropylate, aluminum oxide isopropoxide trimmer, aluminum oxide octylate trimmer, calcium methoxide, calcium ethoxide, calcium isopropoxide, calcium acetylacetonate, gallium methoxide, gallium ethoxide, gallium isopropoxide, gallium acetylacetonate, germanium methoxide, germanium ethoxide, germanium isopropoxide, germanium n-butoxide, germanium tert-butoxide, ethyltriethoxy germanium, strontium isopropoxide, tris(2,4-pentanedionato) indium, indium isopropoxide, indium n-butoxide, indium methoxyethoxide, tin n-butoxide, tin tert-butoxide, tin acetylacetonate, barium diisopropoxide, barium tert-butoxide, barium acetylacetonate, thallium ethoxide, thallium acetylacetonate, and lead acetylacetonate.

Among these metal alkoxide compounds, a compound having a branched alkoxy group is preferable and a compound having a 2-propoxy group or a sec-but oxy group is more preferable from the viewpoint of reactivity, solubility, and the like. In addition, a compound having an ethoxy group is preferable from the viewpoint of gas barrier performance, adhesive property, and the like.

Furthermore, a metal alkoxide compound having an acetylacetonate group is also preferable. The acetylacetonate group is preferable since it has interaction with the central element of the alkoxide compound by the carbonyl structure and thus handling thereof is easy. Even more preferably, a compound having plural species of the alkoxide group or acetylacetonate group described above is more preferable from the viewpoint of the reactivity or the film composition.

In addition, as the central element (additive element) of the metal alkoxide compound is preferably an element which easily forms a coordinate bond with the nitrogen atom in the polysilazane, and Al or B which exhibits high Lewis acidity is more preferable.

Specific examples of the even more preferable metal alkoxide compound may include magnesium ethoxide, triisopropyl borate, aluminum tri-sec-butoxide, aluminum ethylacetoacetate diisopropylate, calcium isopropoxide, indium isopropoxide, gallium isopropoxide, aluminum diisopropylate mono-sec-butyrate, aluminum ethylacetoacetate di-n-butyrate, and aluminum diethylacetoacetate mono-n-butyrate.

As the metal alkoxide compound, a commercially available product or a synthesized product may be used. Specific examples of the commercially available product may include the AMD (aluminum diisopropylate mono-sec-butyrate), the ASBD (aluminum secondary butyrate), the ALCH (aluminum ethylacetoacetate diisopropylate), the ALCH-TR (aluminum tris-ethylacetoacetate), the aluminum chelate M (aluminum alkylacetoacetate diisopropylate), the aluminum chelate D (aluminum bis-ethylacetoacetate mono-acetylacetonate), and the aluminum chelate A (W) (aluminum tris-acetylacetonate) (all of them are manufactured by Kawaken Fine Chemicals Co., Ltd.), the PLENACT (registered trademark) AL-M (acetoalkoxy aluminum diisopropylate, manufactured by Ajinomoto Fine-Techno Co., Inc.), and the ORGATICS series (manufactured by Matsumoto Fine Chemical Co., Ltd.).

Incidentally, in the case of using a metal alkoxide compound, it is preferable to mix the metal alkoxide compound with the coating liquid containing a polysilazane in an inert gas atmosphere. This is because in order to suppress that the metal alkoxide compound reacts with moisture or oxygen in the air to be violently oxidized.

In addition, it is possible to use a compound as mentioned below as an additive compound other than the metal alkoxide compound.

Aluminum Compound

Anorthoclase, alumina, an aluminosilicate salt, aluminic acid, sodium aluminate, alexandrite, ammonium leucite, yttrium aluminum garnet, yellow feldspar, osarizawaite, omphacite, pyroxene, sericite, gibbsite, sanidine, sapphire, aluminum oxide, aluminum oxide hydroxide, aluminum bromide, aluminum dodecaboride, aluminum nitrate, white mica, aluminum hydroxide, aluminum lithium hydride, sugilite, spinel, diaspore, aluminum arsenide, peacock (pigment), microcline, jadeite, cryolite, hornblende, aluminum fluoride, zeolite, brazilianite, vesuvianite, B alumina solid electrolyte, pezzottaite, sodalite, an organic aluminum compound, spodumene, lithia mica, aluminum sulfate, beryl, chlorite, epidote, aluminum phosphide, aluminum phosphate, and the like.

Magnesium Compound

Zinc-melanterite, magnesium sulfite, magnesium benzoate, carnallite, magnesiumperchlorate, magnesium peroxide, talc, enstatite, olivine, magnesium acetate, magnesium oxide, serpentinite, magnesium bromide, magnesium nitrate, magnesium hydroxide, spinel, hornblende, augite, magnesium fluoride, magnesium sulfide, magnesium sulfate, magnesite, and the like.

Calcium Compound

Aragonite, calcium sulfite, calcium benzoate, Egyptian Blue, calcium chloride, calcium chloride hydroxide, calcium chlorate, uvarovite, scheelite, hedenbergite, zoisite, calcium peroxide, superphosphate of lime, calcium cyanamide, calcium hypochlorite, calcium cyanide, calcium bromide, double superphosphate of lime, calcium oxalate, calcium bromate, calcium nitrate, calcium hydroxide, hornblende, augite, calcium fluoride, fluorapatite, calcium iodide, calcium iodate, johannsenite, calcium sulfide, calcium sulfate, actinolite, epidote, epidote, autunite, apatite, calcium phosphate, and the like.

Gallium Compound

Gallium(III) oxide, gallium(III) hydroxide, gallium nitride, gallium arsenide, gallium(III) iodide, gallium phosphate, and the like.

Boron Compound

Boron oxide, boron tribromide, boron trifluoride, boron triiodide, sodium cyanoborohydride, diborane, boric acid, trimethyl borate, borax, borazine, borane, boronic acid, and the like.

Germanium Compound

An organic germanium compound, an inorganic germanium compound, germanium oxide, and the like.

Indium Compound

Indium oxide, indium chloride, and the like.

<Coating Liquid>

As the solvent for preparing the coating liquid for the formation of coating layer (hereinafter, also referred to as the coating liquid for coating layer formation) is not particularly limited as long as it can dissolve or disperse the polysilazane and/or the additive compound, but an organic solvent that does not contain water and a reactive group (for example, a hydroxyl group or an amine group) which readily react with the polysilazane and is inert to the polysilazane is preferable and an aprotic organic solvent is more preferable. Specific examples of the solvent may include an aprotic solvent; for example a hydrocarbon solvent such as an aliphatic hydrocarbon, an alicyclic hydrocarbon, and an aromatic hydrocarbon including pentane, hexane, cyclohexane, toluene, xylene, Solvesso, and turpentine; a halogenated hydrocarbon solvent such as methylene chloride or trichloroethane; an ester such as ethyl acetate or butyl acetate; a ketone such as acetone or methyl ethyl ketone; and an ether such as an aliphatic ether or an alicyclic ether including dibutyl ether, dioxane, and tetrahydrofuran: for example, tetrahydrofuran, dibutyl ether, mono-alkylene glycol dialkyl ether, and polyalkylene glycol dialkyl ether (a diglyme). The above solvents may be used singly or in the form of a mixture of two or more kinds thereof.

The concentration of the polysilazane in the coating liquid for coating layer formation is not particularly limited and varies depending on the film thickness of the gas barrier layer or the pot life of the coating liquid, but it is preferably about from 0.2 to 35% by mass.

In addition, the amount of the additive compound used in the coating liquid for coating layer formation in the case of using an additive compound is not particularly limited, but it is preferably a mass to be from 0.01 to 10 times and more preferably a mass to be from 0.06 to 6 times the mass of solid content of the polysilazane.

It is preferable that the coating liquid for coating layer formation contains a catalyst in order to promote the modification. As the catalyst that can be applied to the present invention, a basic catalyst is preferable, and particular examples thereof may include an amine catalyst such as N,N-diethylethanolamine, N,N-dimethylethanolamine, triethanolamine, triethylamine, 3-morpholinopropylamine, N,N,N′,N′-tetramethyl-1,3-diaminopropane, or N,N,N′,N′-tetramethyl-1,6-diaminohexane, a metal catalyst such as a Pt compound including Pt acetylacetonate, a Pd compound including Pd propionate, a Rh compound including Rh acetylacetonate, and a N-heterocyclic compound. Among these, it is preferable to use an amine catalyst. The concentration of the catalyst to be added at this time is preferably from 0.01 to 2% by mass with respect to the polysilazane. It is possible to avoid the excessive formation of silanol due to rapid progress of the reaction, a decrease in film density, an increase of the film defects, and the like as the amount of the catalyst added is adjusted to be in this range.

In addition, it is possible to use the additives to be mentioned below in the coating liquid for coating layer formation if necessary. The additives are, for example, a cellulose ether and a cellulose ester; for example, ethyl cellulose, nitrocellulose, cellulose acetate, and cellulose acetobutyrate, and a natural resin; for example, rubber or a rosin resin, a synthetic resin; for example, a polymerization resin, a condensation resin; for example, aminoplast, in particular, a urea resin, a melamine-formaldehyde resin, an alkyd resin, an acrylic resin, a polyester or a modified polyester, an epoxide, a polyisocyanate or a blocked polyisocyanate, and a polysiloxane.

<Method for Coating Coating Liquid>

In the present invention, a method for coating the coating liquid for coating layer formation is a simultaneous multilayer coating method, and a suitable simultaneous multilayer coating method known in the prior art is adopted. Specific examples thereof may include a slide type curtain coating method, a slide hopper coating method described in U.S. Pat. No. 2,761,419 and U.S. Pat. No. 2,761,791, and an extrusion coating method.

It is possible to obtain a plurality of coating layers by conducting the coating step and the drying step only one time as such simultaneous multilayer coating is conducted. Hence, according to the present invention, it is possible to suppress curling of the film, thermal deterioration of the substrate, and the like even though the substrate is thinned, and it is possible to obtain a gas barrier film which exhibits excellent gas barrier property and excellent interlayer adhesive force and bending resistance after being stored in a high temperature and high humidity condition. Consequently, the gas barrier film of the present invention can contribute to weight saving or thinning of an electronic device.

Hereinafter, simultaneous multilayer coating by the slide hopper coating method that is a preferred producing method (coating method) of the present invention will be described in detail.

The coating and drying method is not particularly limited, but it is preferable to warm the coating liquid for coating layer formation to 20° C. or higher, to conduct the simultaneous multilayer coating of the coating liquid on the substrate (transparent resin film), then once to cool (setting) the coating layer thus formed to a temperature of preferably from 1 to 15° C., and then to dry at 10° C. or higher. A more preferred drying condition is a condition in which the wet-bulb temperature is adjusted to be in a range of from 5 to 50° C. and the film surface temperature is adjusted to be in a range of from 10 to 50° C. In addition, as the cooling method immediately after coating, it is preferable to conduct cooling by a horizontal setting method from the viewpoint of an improvement in uniformity of the formed coating layer.

Here, setting described above means a step of decreasing the fluidity of the material between the respective layers and in the respective layers by increasing the viscosity of the coating liquid through a means to apply cold air or the like to the coating layer to lower the temperature. The state that nothing is stuck to the finger when cold air is blown to the surface of the coating layer and then the surface of the coating layer is pressed by a finger is defined as the state that the setting is completed.

The time (setting time) from cold air is blown until the setting is completed after coating is preferably within 5 minutes. In addition, the lower limit of the time is not particularly limited, but it is preferable to take a time of 45 seconds or longer.

The setting time can be adjusted by adjusting the concentration of the polysilazane or the concentration of the additive compound.

The temperature of cold air is preferably from 0 to 25° C. and more preferably from 5 to 20° C. In addition, the time that the coating layer is exposed to cold air is preferably from 10 to 120 seconds although it is also dependent on the conveying speed of the coating layer.

The coating thickness (thickness before drying) of the coating liquid can be appropriately set according to the purpose. For example, the thickness (thickness after drying) per one coating layer is preferably from 0.1 to 1000 nm, more preferably from 1 to 800 nm, and even more preferably from 5 to 500 nm. Incidentally, the thickness of each of the plural coating layers may be the same as or different from one another. The coating thickness of the coating liquid can be adjusted so that the thickness of the coating layer after drying is in such a range.

The coating film is dried after coating the coating liquid. It is possible to remove the organic solvent contained in the coating film by drying the coating film. At this time, the organic solvent contained in the coating film may be completely dried, but a part thereof may be left. A suitable gas barrier layer can be obtained even in the case of leaving a part of the organic solvent. Incidentally, the residual solvent can be removed later.

The drying temperature of the coating layer varies depending on the substrate to be applied, but it is preferably from 30 to 200° C. For example, in the case of using a polyethylene terephthalate substrate having a glass transition temperature (Tg) of 70° C. as the substrate, the drying temperature is preferably set to 150° C. or lower in consideration of the deformation of the substrate by heat. The above temperature can be set using a hot plate, an oven, a furnace, and the like. It is preferable to set the drying time to be a short period of time, and for example, it is preferable to set it to be within 30 minutes in a case in which the drying temperature is 150° C. In addition, the drying atmosphere may be any condition of an air atmosphere, a nitrogen atmosphere, an argon atmosphere, a vacuum atmosphere, a reduced pressure atmosphere having a controlled concentration of oxygen.

The coating layer obtained by coating the coating liquid containing a polysilazane may include the step of removing moisture before the modification treatment or during the modification treatment. As the method for removing moisture, a form to dehumidify by maintaining a low humidity environment is preferable. The humidity in the low humidity environment changes depending on the temperature, and thus a preferred form of the relation between the temperature and the humidity is indicated by the rule of dew-point temperature. A preferred dew-point temperature is 4° C. (temperature of 25° C./humidity of 25%) or lower and a more preferred dew-point temperature is −5° C. (temperature of 25° C./humidity of 10%) or lower, and it is preferable to appropriately set the time to maintain a low humidity environment depending on the film thickness of the gas barrier layer. It is preferable that the dew-point temperature is −5° C. or lower and the time to maintain a low humidity environment is 1 minute or longer under a condition that the film thickness of the gas barrier layer is 1.0 μm or less. Incidentally, the lower limit of the dew-point temperature is not particularly limited, but it is usually at −50° C. or higher and preferably −40° C. or higher. It is a preferred form to remove moisture before the modification treatment or during the modification treatment from the viewpoint of promoting the dehydration reaction of the gas barrier layer that is converted into a silanol.

<Modification Treatment of Coating Layer>

The modification treatment of the coating layer in the present invention refers to a reaction that a part or all of the polysilazanes contained in the coating layer obtained above is converted into silicon oxide, silicon nitride, silicon oxynitride, and the like, and specifically it refers to a reaction to form an inorganic thin film in the level capable of contributing to that the gas barrier film of the present invention exerts gas barrier property as a whole.

The modification treatment in the present invention is conducted by irradiating the coating layers with vacuum ultraviolet rays from the side of the farthest coating layer from the substrate. Ozone or an active oxygen atom generated by ultraviolet rays (synonymous with ultraviolet light) exhibits high oxidizing ability, and thus it is possible to form a silicon oxide film, a silicon nitride film, a silicon oxynitride film, and the like which exhibits high denseness and insulating property at a low temperature.

By this ultraviolet ray irradiation, the substrate is heated, and O₂ and H₂O contributing to the formation of ceramic (conversion into silica) or an ultraviolet absorber and a polysilazane itself are excited and activated, and thus the polysilazane is excited, the excited polysilazane is promoted to form ceramic, and also the gas barrier layer to be obtained is further densified. In addition, at least one layer of the gas barrier layers before being subjected to the modification treatment contains an additive element, and thus by only irradiating the plurality of coating layers with vacuum ultraviolet rays from the outermost layer side thereof one time, the modification uniformly proceeds from the surface to the inside of the farthest coating layer from the substrate and a layer below the layer in the same manner, and the modification proceeds in a layer further below the layer and a layer even further below the layer so that the modification uniformly proceeds in the film thickness direction. Consequently, a gas barrier film which hardly cracks, exhibits excellent interlayer adhesive force and bending resistance, and hardly exhibits deteriorated gas barrier property even after being stored under a high temperature and high humidity condition is obtained.

In the vacuum ultraviolet ray irradiation treatment, it is also possible to use any one of the ultraviolet ray generators that are commonly used. Incidentally, the ultraviolet rays referred to in the present invention generally refers to ultraviolet light containing an electromagnetic wave having a wavelength of from 10 to 200 nm.

Upon vacuum ultraviolet light irradiation, it is preferable to set the irradiation intensity and irradiation time to be in the range in which the substrate supporting the coating layer to be irradiated is not damaged.

When the case of using a plastic film as the substrate is taken as an example, it is possible to set the distance between the substrate and the ultraviolet ray irradiating lamp so that the intensity on the substrate surface becomes from 20 to 300 mW/cm² and preferably from 50 to 200 mW/cm² and to conduct irradiation for from 0.1 second to 10 minutes using a lamp of 2 kW (80 W/cm×25 cm), for example.

In general, when the substrate temperature at the time of the vacuum ultraviolet ray irradiation treatment reaches 150° C. or higher, the substrate is deformed or its strength deteriorates so that the properties of the substrate are impaired in the case of a plastic film and the like. However, the modification treatment can be conducted at a higher temperature in the case of a film such as a polyimide which exhibits high heat resistance. Hence, the substrate temperature at the time of this ultraviolet ray irradiation does not have a general upper limit, and it is possible to appropriately set the substrate temperature depending on the kind of substrate by those skilled in the art. In addition, the ultraviolet ray irradiation atmosphere is not particularly limited.

The ultraviolet ray irradiation is adaptable to a batch treatment or a continuous treatment, and thus the type of treatment can be appropriately selected depending on the shape of the substrate to be used. For example, in the case of a batch treatment, it is possible to treat a stacked body having a coating layer on the surface using an ultraviolet ray furnace equipped with a vacuum ultraviolet ray generating source as mentioned above. The ultraviolet ray furnace itself is generally known, and for example, it is possible to use an ultraviolet ray furnace manufactured by EYE GRAPHICS Co., Ltd. In addition, in a case in which the stacked body having a coating layer on the surface has a long film shape, it is possible to form ceramic by continuously irradiating the stacked body with ultraviolet rays in the drying zone equipped with an ultraviolet ray generating source as mentioned above while conveying this. The time required for ultraviolet ray irradiation is generally from 0.1 second to 10 minutes and preferably from 0.5 seconds to 3 minutes although it is also dependent on the substrate to be used or the composition and concentration of the gas barrier layer.

In the modification treatment by vacuum ultraviolet ray irradiation, an oxidation reaction by active oxygen or ozone proceeds while directly breaking the bond between atoms by only the action of photons called photon process using the energy of light having a wavelength of preferably from 100 to 200 nm and more preferably from 100 to 180 nm that is stronger than the interatomic bonding force in the polysilazane compound. By virtue of this, it is possible to conduct the formation of an inorganic thin film at a relatively low temperature (about 200° C. or lower).

Examples of such a vacuum ultraviolet ray generating means may include a metal halide lamp, a high pressure mercury lamp, a low pressure mercury lamp, a xenon arc lamp, a carbon arc lamp, an excimer lamp, and a UV light laser, but the vacuum ultraviolet ray generating means is not particularly limited. In addition, when irradiating the polysilazane coating layer before being modified with the generated vacuum ultraviolet rays, it is desirable that the vacuum ultraviolet rays from the generating source strikes the polysilazane coating layer before being modified after being reflected from the reflective plate from the viewpoint of improving the efficiency and achieving uniform irradiation. As the vacuum ultraviolet ray source in the present invention, a noble gas excimer lamp is preferably used.

Incidentally, the atoms of the noble gases such as Xe, Kr, Ar, and Ne are referred to as inert gases since the atoms thereof do not chemically bond to form a molecule. However, the atoms (excited atoms) of the noble gases which have gained energy through electric discharge and the like can bond with other atoms to form a molecule. In a case in which the noble gas is xenon, the reaction is as follows:

e+Xe→e+Xe*

Xe*+Xe+Xe→Xe₂*+Xe

and excimer light (vacuum ultraviolet light) of 172 nm emits when Xe₂* that is the excited excimer molecule returns to the ground state.

As the characteristics of the excimer lamp, it is mentioned that radiation is concentrated on one wavelength, light other than the required light is hardly radiated, and thus the efficiency is high. In addition, it is possible to maintain the temperature of the target low since extra light is not radiated. Moreover, instantaneous turning on and off is possible since it does not require the time for start and restart.

In order to obtain the excimer light emission, a method to use a dielectric barrier discharge is known. The dielectric barrier discharge is significantly fine electric discharge called micro discharge that is similar to lightning and occurs in the gas space by disposing the gas space between two electrodes via a dielectric (transparent quartz in the case of excimer lamp) and applying a high frequency and high voltage of several tens kHz to the electrodes.

In addition, electrodeless field discharge is also known as the method for efficiently obtaining the excimer light emission in addition to the dielectric barrier discharge. The electrodeless field discharge is electric discharge caused by capacitive coupling and also referred to as RF discharge. The lamp and the electrode and their disposition may be basically the same as the dielectric barrier discharge, but the high frequency applied between both electrodes is turned on at several MHz. As described above, electric discharge that is spatially and temporally consistent is obtained by electrodeless field discharge.

In addition, the Xe excimer lamp has an excellent light emission efficiency since it radiates ultraviolet rays having a short wavelength of 172 nm as a single wavelength. This light has a high absorption coefficient of oxygen and thus can generate a radical oxygen atomic species or ozone at a high concentration with a trace amount of oxygen. In addition, it is known that the energy of light which has a short wavelength of 172 nm and thus dissociates the bonding of an organic substance exhibits high ability. It is possible to realize the modification of the polysilazane film in a short period of time by this active oxygen or ozone and the high energy due to ultraviolet radiation. Accordingly, it is possible to conduct the modification treatment with a high throughput and to shorten the process time or to decrease the area for the equipment as compared to a low pressure mercury lamp which emits light of a wavelength of 185 nm and 254 nm or plasma cleaning.

In addition, the excimer lamp has a high light generating efficiency, and thus it is possible to turn on the excimer lamp by inputting a lower electrical power. Moreover, the excimer lamp does not emit light of a longer wavelength which causes a temperature rise due to light and irradiates the energy of a single wavelength in the ultraviolet region, and thus it has a characteristic that an increase in temperature of the surface of the irradiation target is suppressed. Hence, the excimer lamp is suitable for irradiation of a gas barrier film which includes an organic material that is easily damaged by heat such as polyethylene terephthalate that is susceptible to heat, a plastic substrate, a resin film, or the like as the substrate.

Oxygen is required in the reaction at the time of vacuum ultraviolet ray irradiation, but vacuum ultraviolet rays are absorbed by oxygen, and thus the efficiency in the ultraviolet ray irradiating step is likely to decrease in an atmosphere containing oxygen. Hence, it is preferable that vacuum ultraviolet ray irradiation is conducted in a state that the concentration of oxygen and the concentration of water vapor are low as possible. In other words, it is preferable to set the concentration of oxygen at the time of vacuum ultraviolet ray irradiation to from 300 to 10,000 ppm by volume (1% by volume), and the concentration of oxygen is more preferably from 500 to 5,000 ppm by volume. In addition, the concentration of water vapor during the conversion process is preferably set to be in a range of from 1,000 to 4,000 ppm by volume.

As the gas which is used at the time of vacuum ultraviolet ray irradiation and fills the irradiation atmosphere, a dry inert gas is preferable, and in particular, a dry nitrogen gas is preferable from the viewpoint of cost. The concentration of oxygen can be adjusted by measuring the flow rate of the oxygen gas and the inert gas to be introduced into the irradiating house and changing the ratio of flow rate.

In vacuum ultraviolet ray irradiation, the intensity of illumination by vacuum ultraviolet rays on the coated surface received by the outermost layer of the coating layers is preferably from 1 mW/cm² to 10 W/cm², more preferably from 30 to 200 mW/cm², and even more preferably from 50 to 160 mW/cm². It is concerned that the modification efficiency greatly decreases when the intensity of illumination is less than 1 mW/cm², and it is concerned that ablation of the coating film occurs or the substrate is damaged when it exceeds 10 W/cm².

The quantity of energy (irradiation quantity, integrated quantity of light) irradiated on the surface of the outermost layer of the coating layers with vacuum ultraviolet rays is preferably from 10 to 20000 mJ/cm², more preferably from 20 to 10000 mJ/cm², and even more preferably from 100 to 8000 mJ/cm². It is concerned that modification insufficiently proceeds when the quantity of irradiation energy is less than 10 mJ/cm², and it is concerned that cracking due to excessive modification or thermal deformation of the substrate occurs when it exceeds 20000 mJ/cm².

In addition, it is also preferably used that the coating layer is heated at the same time with vacuum ultraviolet ray irradiation in order to promote the modification treatment. Examples of the heating method may include a method in which the substrate is brought into contact with a heat-generating body such as a heat block and the coating layer is heated by heat conduction, a method in which the atmosphere is heated by an external heater with a resistance wire or the like, and a method in which light in the infrared region such as an IR heater or the like is used, but the method is not particularly limited, and the method can be appropriately selected in a range in which the smoothness of the coating layer can be maintained. The irradiation condition (heating condition) of vacuum ultraviolet rays varies depending on the substrate to be applied, and it can be appropriately determined by those skilled in the art. For example, the irradiation temperature (heating temperature) of vacuum ultraviolet rays is preferably from 50 to 200° C. and more preferably from 80 to 150° C. It is preferable that the irradiation condition (heating condition) is within the above range since the deformation of the substrate or the deterioration in strength hardly occurs and the properties of the substrate are not impaired. The irradiation time (heating time) is preferably set to be in a range of from 1 second to 10 hours and more preferably from 10 seconds to 1 hour.

In addition, the vacuum ultraviolet light that is used for the modification may be generated by a plasma formed with a gas containing at least one kind of CO, CO₂, and CH₄. Moreover, as the gas containing at least one kind of CO, CO₂, and CH₄ (hereinafter, also referred to as the carbon-containing gas), the carbon-containing gas may be used singly, but it is preferable to use a noble gas or H₂ as the main gas and to add a small amount of the carbon-containing gas. As the plasma generating method, capacitively coupled plasma and the like are mentioned.

Next, the reaction mechanism by which silicon oxynitride and further silicon oxide are presumed to be produced from perhydropolysilazane through vacuum ultraviolet ray irradiation in a case in which the polysilazane is perhydropolysilazane that is a preferred form will be described below.

(I) Dehydrogenation and Formation of Si—N Bond Associated with it

It is believed that the Si—H bond or N—H bond in perhydropolysilazane is relatively easily broken by excitation and the like due to vacuum ultraviolet ray irradiation and a Si—N bond is formed in an inert atmosphere (dangling bond of Si is formed in some cases). In other words, perhydropolysilazane is not oxidized but cured to have a SiN_{y} composition. In this case, the breaking of the polymer backbone does not occur. The breaking of the Si—H bond or the N—H bond is promoted by the presence of a catalyst or heating. Broken H is released to the outside of the film as H₂.

(II) Formation of Si—O—Si Bond by Hydrolysis and Dehydration Condensation

The Si—N bond in perhydropolysilazane is hydrolyzed by water and the polymer backbone is broken to form Si—OH. Two Si—OH form a Si—O—Si bond by dehydration condensation to be cured. This is a reaction that also occurs in the air, but the water vapor that is generated as outgas from the substrate by the heat due to irradiation is believed to be a main water source during vacuum ultraviolet ray irradiation in an inert atmosphere. When the moisture is excessive, Si—OH that has not been subjected to the dehydration condensation remains and a cured film that is represented by a composition of SiO_{2.1} to SiO_{2.3} and exhibits low gas barrier property is obtained.

(III) Direct Oxidation by Singlet Oxygen and Formation of Si—O—Si Bond

Singlet oxygen which exhibits significantly strong oxidizing power is formed when an adequate amount of oxygen is present in the atmosphere during vacuum ultraviolet ray irradiation. H or N in perhydropolysilazane is replaced with O to form a Si—O—Si bond to be cured. It is believed that the recombination of bonding by breakage of the polymer backbone occurs in some cases.

(IV) Oxidation Accompanied by Breakage of Si—N Bond by Vacuum Ultraviolet Ray Irradiation and Excitation

The energy of vacuum ultraviolet rays is higher than the bond energy of Si—N in perhydropolysilazane, and thus it is believed that the Si—N bond is broken and oxidation occurs to forma Si—O—Si bond or a Si—O—N bond when oxygen sources such as oxygen, ozone, and water are present near there. It is believed that the recombination of bonding by breakage of the polymer backbone occurs in some cases.

The adjustment of the composition of silicon oxynitride in the gas barrier layer obtained by irradiating the coating layer containing a polysilazane with vacuum ultraviolet rays can be carried out by controlling the oxidation state through appropriate combination of the oxidation mechanisms of (I) to (IV) described above.

Here, in the case of the polysilazane, the breakage of the Si—H and N—H bonds and the formation of the Si—O bond occur and the conversion into ceramic such as silica occurs in silica conversion (modification treatment), but the degree of conversion can be semiquantitatively evaluated by the SiO/SiN ratio expressed by the following definitional Equation (1) obtained through the IR measurement.

[Mathematical Formula 1]

SiO/SiN ratio=(absorbance of SiO after conversion)/(absorbance of SiN after conversion) Equation (1)

Here, the absorbance of SiO and the absorbance of SiN are calculated from the absorption (absorbance) at about 1160 cm⁻¹ and about 840 cm⁻¹, respectively. It indicates that the conversion into ceramic that is closer to the silica composition has further proceeded as the SiO/SiN ratio is greater.

Here, the SiO/SiN ratio to be an indicator of the degree of conversion into ceramic is preferably 0.3 or more and more preferably 0.5 or more. There is a case in which expected gas barrier property is not obtained when the degree of conversion is less than 0.3. In addition, as the method for measuring the rate of silica conversion (x in SiOₓ), for example, it can be measured using the XPS method.

The chemical composition of the gas barrier layer can be determined by measuring the atomic composition ratio using an XPS surface analyzer. In addition, it is also possible to determine the chemical composition by cutting the gas barrier layer and measuring the atomic composition ratio of the cut surface using an XPS surface analyzer.

The chemical composition of the gas barrier layer can be controlled by the kind and amount of the polysilazane, additive compound, and the like that are used when forming the gas barrier layer, the condition when modifying the coating layer, and the like.

The thickness per one gas barrier layer is required to be set so as to achieve both of gas barrier property and flexibility, there is a risk that gas barrier property decreases when one gas barrier layer is too thin, and there is a risk that a decrease in flexibility or fissure of the film occurs when it is too thick. The thickness per one gas barrier layer is preferably is from 0.1 to 1000 nm, more preferably from 1 to 800 nm, and even more preferably from 5 to 500 nm as the thickness after drying. The thickness per one gas barrier layer can be measured, for example, using a transmission electron microscope.

[Gas Barrier Layer Formed by Deposition Method]

The gas barrier film of the present invention may further include a gas barrier layer formed by a deposition method (hereinafter, also simply referred to as the deposited gas barrier layer).

The film thickness of the deposited gas barrier layer to be described here is not particularly limited, but it is preferably from 1 to 800 nm and more preferably from 5 to 500 nm. The deposited barrier layer exhibits excellent gas barrier performance, folding resistance, cutting processing suitability, and the like when the film thickness is in such a range.

In addition, the elastic modulus of the deposited gas barrier layer is preferably from 15 to 45 GPa and more preferably from 20 to 40 GPa. The gas barrier performance, folding resistance, and cutting processing suitability are obtained when the elastic modulus is in this range. Incidentally, the elastic modulus can be measured by a nanoindentation method.

The deposition method is not particularly limited, and a known thin film deposition technique can be used. Examples thereof may include a deposition method, a reactive deposition method, a sputtering method, a reactive sputtering method, and a chemical vapor deposition method.

Reactive Deposition Method

The reactive deposition method is a method in which a reactive gas is introduced into a vacuum vessel and allowed to react with atoms and molecules evaporated from the evaporation source to deposit the resultant, and it is possible to introduce an excitation source such as a plasma in order to promote the reaction. As typical raw materials, silicon, silicon nitride, silicon oxide, silicon oxynitride, and the like are used as the deposition source and nitrogen, hydrogen, ammonia, oxygen and the like are used as the reactive gas.

Sputtering Method

The sputtering method is a method in which the constituent atom of the target sputtered is deposited on a substrate, by utilizing a sputtering phenomenon that a high energy ion accelerated by an electric field strikes and bombards the target to eject the constituent atom of the target. The reactive sputtering method is a method in which a reactive gas is introduced into a vacuum vessel and allowed to react with the constituent atom of the sputtered target to deposit the resultant on a substrate. As typical raw materials, silicon, silicon nitride, silicon oxide, silicon oxynitride, and the like are used as the target material and nitrogen, hydrogen, ammonia, oxygen and the like are used as the reactive gas.

Chemical Vapor Deposition Method

The chemical vapor deposition method is a method in which a material gas containing a constituent element of the film is introduced into a vacuum vessel and the material gas is excite d by a particular excitation source to form excited species by a chemical reaction and to deposit it on a substrate. As typical raw materials, monosilane, hexamethyldisilazane, ammonia, nitrogen, hydrogen, oxygen, and the like are used.

The chemical vapor deposition method is a more promising technique since it is possible to form a film at a high speed and coatability with respect to the substrate is more favorable as compared to the sputtering method and the like. In particular, the catalytic chemical vapor deposition (Cat-CVD) method to use a catalytic body at a significantly high temperature as the excitation source or the plasma-enhanced chemical vapor deposition (PECVD) method to use a plasma as the excitation source is a preferred method. Hereinafter, these techniques will be described in detail.

Cat-CVD Method

The Cat-CVD method is a method in which a material gas is allowed to flow into a vacuum vessel having a wire made of tungsten or the like arranged therein, the decomposition reaction of the material gas occurs by the wire that is electrically heated by a power supply, and the reactive species thus generated is deposited on a substrate.

For example, in the case of depositing silicon nitride, monosilane, ammonia, and hydrogen are used as the material gas. In the case of depositing silicon oxynitride, oxygen is added in addition to the above material gas. As a condition example, tungsten wire (example: φ of 0.5 mm, length of 2.8 m) of a catalytic body is electrically heated to 1800° C., monosilane, ammonia, and hydrogen (4/200/200 sccm) as the material gas are allowed to flow through, the pressure is maintained at 10 Pa, and a film is deposited on a substrate having a controlled temperature of 100° C. Among the reactive species generated by the decomposition reaction on the catalytic body, the main deposition species is SiH₃* and NH₂*, and H* is the reaction auxiliary species on the film surface. In particular, it is possible to generate a great amount of H* by adding hydrogen, and thus it is believed that the reaction to remove H derived from the Si—H bond or N—H bond in the film is promoted although the deposition rate decreases.

PECVD Method

The PECVD method is a method in which a material gas is allowed to flow into a vacuum vessel equipped with a plasma source, a discharge plasma is generated in the vacuum vessel by supplying the electrical power from the power supply to the plasma source, the material gas is subjected to the decomposition reaction by the plasma, and the reactive species thus generated is deposited on a substrate. As the method of the plasma source, a capacitively coupled plasma using parallel plate electrodes, an inductively coupled plasma, a microwave excited plasma utilizing a surface wave, or the like is used.

The deposited gas barrier layer obtained by the vacuum plasma CVD method and the plasma CVD method under the atmospheric pressure or a pressure near the atmospheric pressure is preferable since it is possible to produce an intended compound by choosing the conditions such as the metal compound that is the primary material (also referred to as the raw material), the decomposition gas, the decomposition temperature, and the input electrical power.

For example, silicon oxide is produced when a silicon compound is used as the raw material compound and oxygen is used as the decomposition gas. This is because significantly active charged particles and active radicals are present in the plasma space at a high density, and thus a multi-step chemical reaction is promoted at a significantly high speed in the plasma space and the elements present in the plasma space are converted into the thermodynamically stable compounds in a significantly short period of time.

As the raw material compound, it is preferable to use a silicon compound, a titanium compound, and an aluminum compound. These raw material compounds can be used singly or in combination of two or more kinds thereof.

Among these, examples of the silicon compound may include silane, tetramethoxysilane, tetraethoxysilane, tetra-n-propoxysilane, tetraisopropoxysilane, tetra-n-butoxysilane, tetra-t-butoxysilane, dimethyldimethoxysilane, dimethyldiethoxysilane, diethyldimethoxysilane, diphenyldimethoxysilane, methyltriethoxysilane, ethyltrimethoxysilane, phenyltriethoxysilane, (3,3,3-trifluoropropyl)trimethoxysilane, hexamethyldisiloxane, bis(dimethylamino)dimethylsilane, bis(dimethylamino)methylvinylsilane, bis(ethylamino)dimethylsilane, N,O-bis(trimethylsilyl)acetamide, bis(trimethylsilyl)carbodiimide, diethylaminotrimethylsilane, dimethylamino dimethylsilane, hexamethyldisilazane, hexamethylcyclotrisilazane, heptamethyldisilazane, nonamethyltrisilane, octamethylcyclotetrasilazane, tetrakisdimethylaminosilane, tetra-isocyanatesilane, tetramethyldisilazane, tris(dimethylamino)silane, triethoxyfluorosilane, allyldimethylsilane, allyltrimethylsilane, benzyltrimethylsilane, bis(trimethylsilyl)acetylene, 1,4-bis-trimethylsilyl-1,3-butadiyne, di-t-butylsilane, 1,3-disilabutane, bis(trimethylsilyl)methane, cyclocyclopentadienyltrimethylsilane, phenyldimethylsilane, phenyltrimethylsilane, propargyltrimethylsilane, tetramethylsilane, trimethylsilylacetylene, 1-(trimethylsilyl)-1-propyne, tris(trimethylsilyl)methane, tris(trimethylsilyl)silane, vinyltrimethylsilane, hexamethyldisilane, octamethylcyclotetrasiloxane, tetramethylcyclotetrasiloxane, hexamethylcyclotetrasiloxane, and M-Silicate 51.

Examples of the titanium compound may include titanium methoxide, titanium ethoxide, titanium isopropoxide, titanium tetra-isopropoxide, titanium n-butoxide, titanium di-isopropoxide bis(2,4-pentanedionate), titanium diisopropoxide bis(2,4-ethylacetoacetate), titanium di-n-butoxide bis(2,4-pentanedionate), titanium acetylacetonate, and butyl titanate dimer.

Examples of the aluminum compound may include aluminum ethoxide, aluminum tri-isopropoxide, aluminum isopropoxide, aluminum n-butoxide, aluminum s-butoxide, aluminum t-butoxide, aluminum acetylacetonate, and triethyl dialuminum tri-s-butoxide.

In addition, examples of the decomposition gas for obtaining an inorganic compound by decomposing a raw material gas containing these metals, and the discharge gas may include a hydrogen gas, a methane gas, an acetylene gas, a carbon monoxide gas, a carbon dioxide gas, a nitrogen gas, an ammonia gas, a nitrous oxide gas, a nitrogen oxide gas, a nitrogen dioxide gas, an oxygen gas, and water vapor. In addition, the above decomposition gas may be mixed with an inert gas such as an argon gas or a helium gas.

It is possible to obtain a desired deposited gas barrier layer by appropriately selecting the raw material gas containing a raw material compound and the decomposition gas. The deposited gas barrier layer formed by the PECVD method is a layer containing an oxide, a nitride, an oxynitride, or an oxycarbide.

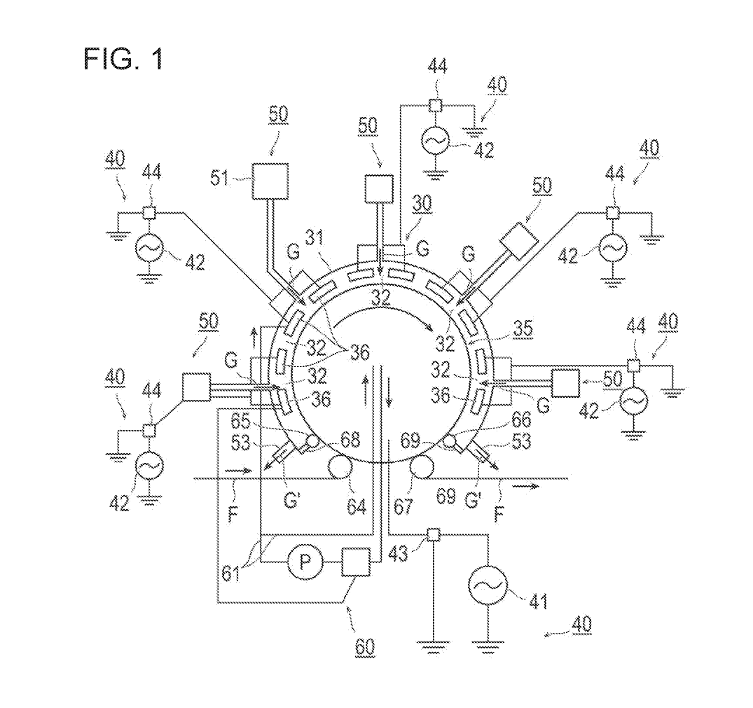

FIG. 1 is a schematic diagram illustrating an example of an atmospheric pressure plasma discharge treatment apparatus that has a system to treat a substrate in the space between counter electrodes and is useful when forming a deposited gas barrier layer according to the present invention.

In the atmospheric pressure plasma discharge treatment apparatus having a system to treat a substrate in the space between the counter electrodes illustrated in FIG. 1, it is possible to obtain a deposited gas barrier layer by changing the gap between the electrodes by inclining the fixed electrode group with respect to the roll rotating electrode or by appropriately selecting the kind of the raw material for film formation to be supplied and the supply amount thereof or the output condition at the time of plasma discharge.

The atmospheric pressure plasma discharge treatment apparatus illustrated in FIG. 1 is an apparatus which includes at least a plasma discharge treatment apparatus 30, an electric field applying means 40 having two power supplies, a gas supply means 50, and an electrode temperature adjusting means 60. In addition, it is an apparatus in which a thin film is formed by subjecting a substrate F to a plasma discharge treatment in a space between counter electrodes 32 (discharge space) formed between a roll rotating electrode (first electrode) 35 and a square tube type fixed electrode (group) (second electrode) 36. In FIG. 1, one electric field is formed by a pair of square tube type fixed electrode groups (second electrode) 36 and the roll rotating electrode (first electrode) 35, and, for example, the formation of a low-density layer is conducted using this one unit. In FIG. 1, a configuration example equipped with a unit having such a configuration at five locations in total is illustrated, and it is possible to continuously form the deposited gas barrier layer by arbitrarily and independently controlling the kind of the raw material to be supplied, the output voltage, and the like in each of the units.

In the discharge space (space between counter electrodes) 32 between the roll rotating electrode (first electrode) 35 and the square tube type fixed electrode group (second electrode) 36, a first high-frequency electric field having a frequency ω₁, an electric field intensity V₁, and a current I₁ is applied to the roll rotating electrode (first electrode) 35 from a first power supply 41 and a second high-frequency electric field having a frequency ω₂, an electric field intensity V₂, and a current I₂ is applied to the square tube type fixed electrode groups (second electrode) 36 from second power supplies 42 corresponding to the respective square tube type fixed electrode groups.

A first filter 43 is installed between the roll rotating electrode (first electrode) 35 and the first power supply 41. The first filter 43 is designed so as to easily pass the current from the first power supply 41 to the first electrode, to ground the current from second power supply 42, and to hardly pass the current from the second power supply 42 to the first power supply. In addition, a second filter 44 is respectively in stalled between the square tube type fixed electrode groups (second electrode) 36 and the second power supplies 42. The second filter 44 is designed so as to easily pass the current from the second power supplies 42 to the second electrode, to ground the current from the first power supply 41, and to hardly pass the current from the first power supply 41 to the second power supply.

Incidentally, in the present invention, the roll rotating electrode 35 may be used as the second electrode and the square tube type fixed electrode group 36 may be used as the first electrode. In any case, the first electrode is connected to the first power supply and the second electrode is connected to the second power supply. It is preferable that the first power supply V₁ applies a higher high-frequency electric field strength than the second power supply V₂ (V₁>V₂). In addition, the frequency has the capacity to become ω₁<ω₂.

In addition, it is preferable that the current is I₁<I₂. The current I₁ of the first high-frequency electric field is preferably from 0.3 to 20 mA/cm² and even more preferably from 1.0 to 20 mA/cm². In addition, the current I₂ of the second high-frequency electric field is preferably from 10 to 100 mA/cm² and even more preferably from 20 to 100 mA/cm².

Gas G that is generated by a gas generator 51 of the gas supply means 50 is introduced into a plasma discharge treatment vessel 31 through an air supply port at a controlled flow rate.

A substrate F is conveyed after being unwound from the original roll that is not illustrated or conveyed from the previous step and passes through a guide roll 64, the air and the like conveyed together with the substrate F is shut off on a nip roll 65, and the substrate F is transferred between the roll rotating electrode 35 and the square tube type fixed electrode group 36 as it is in contact with the roll rotating electrode 35 while being wound. The electric field is applied from both the roll rotating electrode (first electrode) 35 and the square tube type fixed electrode group (second electrode) 36 to generate a discharge plasma in the space between counter electrodes (discharge space) 32. A thin film is formed on the substrate F (the substrate referred to here also includes a treated substrate or a form to have an intermediate layer on a substrate) by gas in a plasma state while the substrate F is wound as it is in contact with the roll rotating electrode 35. The substrate F passes through the nip roll 66 and a guide roll 67, and is wound around a winder that is not illustrated or is transported to the next step.

The treatment waste gas G′ used in the electric discharge treatment is discharged through an exhaust port 53.

In order to heat or cool the roll rotating electrode (first electrode) 35 and the square tube type fixed electrode group (second electrode) 36 during the thin film formation, the temperature is adjusted from the inside of the electrodes by sending a medium having a temperature adjusted by the electrode temperature adjusting means 60 to both of the electrodes via a pipe 61 by a liquid feeding pump P. Incidentally, 68 and 69 are part it ion plates to part it ion the plasma discharge treatment vessel 31 and the outside world.

As the film forming gas (raw material gas and the like) that is supplied from the gas generator 51 to the space between counter electrodes (discharge space) 32, it is possible to use a raw material gas, a decomposition gas, and a discharge gas singly or by mixing two or more kinds thereof. As the raw material gas, the decomposition gas, the discharge gas that are used at this time, the raw material compound, the decomposition gas, and the discharge gas that are described above can be appropriately used.

As the plasma discharge treatment vessel 31, a treatment vessel made of Pyrex (registered trademark) glass is preferably used, but it is also possible to use a treatment vessel made of a metal as long as it is insulated from the electrodes. For example, a polyimide resin or the like may be stuck to the inner surface of a frame made of aluminum or stainless steel, or the metal frame may be subjected to the ceramic thermal spraying to secure insulating property. In FIG. 1, it is preferable to cover both surfaces (up to near the substrate surface) of both of the parallel electrodes with a thing having material nature as mentioned above.

Examples of the first power supply (high-frequency power supply) to be installed in the atmospheric pressure plasma discharge treatment apparatus may include the following commercially available electrodes: Applied power supply symbol, Manufacturer, Frequency, and Product name

### A1 SINFONIA TECHNOLOGY CO., LTD. 3 kHz SPG3-4500

### A2 SINFONIA TECHNOLOGY CO., LTD. 5 kHz SPG5-4500

### A3 KASUGA ELECTRIC WORKS LTD. 15 kHz AGI-023

### A4 SINFONIA TECHNOLOGY CO., LTD. 50 kHz SPG50-4500

A5 HAIDENLABORATORY 100 kHz* PHF-6k

### A6 PEARL KOGYO Co., Ltd. 200 kHz CF-2000-200k and

### A7 PEARL KOGYO Co., Ltd. 400 kHz CF-2000-400k

and it is possible to use any of them.

In addition, examples of the second power supply (high-frequency power supply) may include the following commercially available electrodes:

Applied power supply symbol, Manufacturer, Frequency, and Product name

### B1 PEARL KOGYO Co., Ltd. 800 kHz CF-2000-800k

### B2 PEARL KOGYO Co., Ltd. 2 MHz CF-2000-2M

### B3 PEARL KOGYO Co., Ltd. 13.56 MHz CF-5000-13M

### B4 PEARL KOGYO Co., Ltd. 27 MHz CF-2000-27M and

### B5 PEARL KOGYO Co., Ltd. 150 MHz CF-2000-150M

and it is possible to use any of them.

Incidentally, among the above power supplies, the mark* indicates the impulse high-frequency power supply (100 kHz in continuous mode) manufactured by HAIDENLABORATORY. The power supplies other than that are a high-frequency power supply which can only apply the continuous sine wave. It is preferable to adopt an electrode which can hold a uniform and stable discharge state by applying such an electric field to the atmospheric pressure plasma discharge treatment apparatus.

An electrical power (power density) of 1 W/cm² or more is supplied to the second electrode (second high-frequency electric field) as the electrical power to be applied between the opposing electrodes, the plasma is generated by exciting the discharge gas, and the energy is applied to the gas for film formation to form a thin film. The upper limit value of the electrical power to be supplied to the second electrode is preferably 50 W/cm² or less and more preferably 20 W/cm² or less. The lower limit value is preferably 1.2 W/cm² or more. Incidentally, the electric discharge area (cm²) refers to the area in the range in which electric discharge occurs of the electrode.

In addition, it is possible to improve the power density while maintaining the uniformity of the second high-frequency electric field by supplying an electrical power (power density) of 1 W/cm² or more to the first electrode (first high-frequency electric field) as well. This makes it possible to generate a further uniform high-density plasma and to achieve both of a further improvement in film formation speed and an improvement in film quality. The upper limit value of the electrical power to be supplied to the first electrode is preferably 50 W/cm² or less. The lower limit value is preferably 5 W/cm² or more.

Here, the waveform of the high-frequency electric field is not particularly limited. There are a continuous sine wave-shaped continuous oscillation mode called the continuous mode and an intermittent oscillation mode to intermittently perform ON/OFF called the pulse mode, and either of them may be adopted, but it is preferable that the waveform of at least the second electrode side (second high-frequency electric field) is a continuous sine wave since a denser and high quality film is obtained.

In addition, the control of the film quality can also be achieved by controlling the electrical power of the second power supply side.

The electrode used in such a thin film forming method by an atmospheric pressure plasma is required to be one that withstands a harsh condition in terms of structure and performance. As such an electrode, those which are obtained by covering a metal base material with a dielectric are preferable.

<Modification Treatment of Deposited Gas Barrier Layer>

In the deposited gas barrier layer, the film thus formed may be subjected to the excimer treatment (modification treatment). As the excimer treatment (vacuum ultraviolet ray treatment), a known method can be used, but the vacuum ultraviolet ray treatment as described in the section of the above-described “<modification treatment of coating layer>” is preferable and further a vacuum ultraviolet ray treatment due to the energy of light having a wavelength of from 100 to 180 nm is preferable.

In the excimer treatment that is applied to the deposited gas barrier layer, the concentration of oxygen when irradiating the deposited gas barrier layer with vacuum ultraviolet rays (VUV) is set to preferably from 300 to 50,000 ppm by volume (5% by volume) and more preferably from 500 to 10,000 ppm by volume. By adjusting the concentration of oxygen to be in such a range, it is possible to activate oxygen in the atmosphere and adequately generate ozone or oxygen radicals without significantly impairing the quantity of vacuum ultraviolet rays that are received by the deposited gas barrier layer. Incidentally, it is preferable to use a dry inert gas as a gas other than this oxygen at the time of vacuum ultraviolet ray irradiation, and it is preferable to use a dry nitrogen gas particularly from the viewpoint of cost. The concentration of oxygen can be adjusted by measuring the flow rate of the oxygen gas and the inert gas to be introduced into the irradiating house and changing the ratio of flow rate.

In a case in which a foreign substance such as an organic substance is present on the surface of the deposited gas barrier layer, a decrease in gas barrier property is caused, or a short circuit of the electrode due to the protrusion of the foreign substance is caused in a case in which this gas barrier film is used as the substrate of an organic EL device, and thus it is concerned that a non-light emitting point called the dark spot is frequently generated. Hence, by conducting the excimer treatment, the foreign substance is decomposed, oxidized, and removed by the energy of vacuum ultraviolet rays and ozone, active oxygen, and the like generated by the energy. This makes it possible to repair the defect as a gas barrier layer or to enhance the surface smoothness, thus it is possible to improve the coating uniformity of a coating liquid containing a polysilazane, and as a result, this leads to an improvement in gas barrier property.

The intensity of illumination of vacuum ultraviolet rays and the quantity of irradiation energy of vacuum ultraviolet rays are not particularly limited, but it is preferable that they are in the same ranges as those in the vacuum ultraviolet ray irradiation treatment of the coating layer containing a polysilazane. Incidentally, in the present invention, the vacuum ultraviolet ray irradiation is conducted from the side of the coating layer containing a polysilazane that is farthest from the substrate, but the modification treatment of the deposited gas barrier layer can also be conducted by this vacuum ultraviolet ray irradiation in the case of forming a coating layer containing a polysilazane on the deposited gas barrier layer, and thus the vacuum ultraviolet ray irradiation may not be conducted immediately after forming the deposited gas barrier layer.

In addition, the position of the deposited gas barrier layer in the gas barrier film of the present invention in the stacking direction is not particularly limited.

[After-Treatment]

It is preferable to subject the gas barrier layer formed by a modification treatment to an after-treatment after being coated with a coating liquid of the previous step or after being subjected to the modification treatment and particularly after being subjected to the modification treatment. The after-treatment described herein also includes a temperature treatment (heat treatment) at a temperature of from 10° C. or higher and less than 800° C. or a humidity treatment at a humidity of 0% RH or more and 100% RH or less or of being immersed in a water bath, and the treatment time is defined as a range selected from the range of from 5 seconds to 48 days. The gas barrier layer may be subjected to both of the temperature treatment and the humidity treatment or only to either one. The temperature treatment is preferable from the viewpoint of an improvement in gas barrier property, an improvement in adhesive property, and the like.

When conducting the temperature treatment, a contact type method to place the gas barrier layer on a hot plate, a non-contact type method to hang the gas barrier layer in an oven and to leave to stand, and the like may be used concurrently or singly regardless of the method.

The preferred condition is that the temperature is from 30 to 300° C., the relative humidity is from 30% to 85% RH, and the treatment time is from 30 seconds to 100 hours in consideration of the productivity, the load on the apparatus, and also the resistance of the resin substrate when using a resin substrate.

[Intermediate Layer]

The gas barrier film of the present invention may include an intermediate layer between the respective gas barrier layers. As the method for forming the intermediate layer, it is possible to apply a method for forming a polysiloxane-modified layer. This method is a method for forming an intermediate layer that is formed as a polysiloxane-modified layer by coating a coating liquid containing a polysiloxane on the gas barrier layer by a wet coating method, drying it, and then irradiating the coating film thus obtained with vacuum ultraviolet rays. Incidentally, in the present invention, the vacuum ultraviolet ray irradiation is conducted from the side of the coating layer containing a polysilazane that is farthest from the substrate, but the polysiloxane-modified layer can also be formed by this vacuum ultraviolet ray irradiation, and thus the vacuum ultraviolet ray irradiation may not be conducted immediately after forming a coating film to be the intermediate layer.

The coating liquid used for forming the intermediate layer in the present invention mainly contains a polysiloxane and an organic solvent.

The polysiloxane that can be applied to the formation of the intermediate layer is not particularly limited, but the organopolysiloxane represented by the following Formula (4) is particularly preferable.

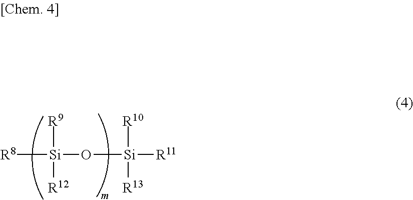

In Formula (4) above, R⁸ to R¹³ each independently represent the same or different organic groups having from 1 to 8 carbon atoms, at this time, at least one of R⁸ to R¹³ is a group containing either of an alkoxy group or a hydroxyl group, and m is 1 or more.

Examples of the organic group having from 1 to 8 carbon atoms represented by R⁸ to R¹³ may include a halogenated alkyl group such as a γ-chloropropyl group or a 3,3,3-trifluoropropyl group, a (meth)acrylic acid-containing acrylic group such as a vinyl group, a phenyl group, or a γ-methacryloxypropyl group, an epoxy-containing alkyl group such as γ-glycidoxypropyl group, a mercapto-containing alkyl group such as a γ-mercaptopropyl group, an amino alkyl group such as a γ-aminopropyl group, an isocyanate-containing alkyl group such as a γ-isocyanatepropyl group, a linear or branched alkyl group such as a methyl group, an ethyl group, a n-propyl group, or an isopropyl group, an alicyclic alkyl group such as a cyclohexyl group or a cyclopentyl group, a linear or branched alkoxy group such as a methoxy group, an ethoxy group, a n-propoxy group, or an isopropoxy group, or an acyl group such as an acetyl group, a propionyl group, a butyryl group, a valeryl group, or a caproyl group.

Moreover, in the present invention, an organopolysiloxane which is represented by Formula (4) above in which m is 1 or more and has the weight average molecular weight of from 1,000 to 20,000 in terms of polystyrene is even more preferable. The intermediate layer to be formed is hardly cracked and the water vapor barrier property can be maintained when the weight average molecular weight of the organopolysiloxane is 1000 or more in terms of polystyrene, and an intermediate layer having a sufficient hardness is obtained when it is 20,000 or less.

In addition, examples of the organic solvent applicable to the formation of the intermediate layer may include an alcohol-based solvent, a ketone-based solvent, an amide-based solvent, an ester-based solvent, and an aprotic solvent.

Here, as the alcohol-based solvent, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, propylene glycol monomethyl ether, propylene glycol monoethyl ether, propylene glycol monopropyl ether, and propylene glycol monobutyl ether are preferable.

Examples of the ketone-based solvent may include a β-diketone such as acetylacetone, 2,4-hexanedione, 2,4-heptanedione 3,5-heptanedione, 2,4-octanedione, 3,5-octanedione, 2,4-nonanedione, 3,5-nonanedione, 5-methyl-2,4-hexanedione, 2,2,6,6-tetramethyl-3,5-heptanedione, or 1,1,1,5,5,5-hexafluoro-2,4-heptanedione in addition to acetone, methyl ethyl ketone, methyl-n-propyl ketone, methyl-n-butyl ketone, diethyl ketone, methyl-iso-butyl ketone, methyl-n-pentyl ketone, ethyl-n-butyl ketone, methyl-n-hexyl ketone, di-iso-butyl ketone, trimethyl nonane, cyclohexanone, 2-hexanone, methylcyclohexanone, 2,4-pentanedione, acetonylacetone, acetophenone, and fenchone. These ketone-based solvents may be used singly or in combination of two or more kinds thereof.

Examples of the amide-based solvent may include formamide, N-methylformamide, N,N-dimethylformamide, N-ethylformamide, N,N-diethylformamide, acetamide, N-methylacetamide, N,N-dimethylacetamide, N-ethylacetamide, N,N-diethylacetamide, N-methylpropionamide, N-methylpyrrolidone, N-formylmorpholine, N-formylpiperidine, N-formylpyrrolidine, N-acetylmorpholine, N-acetylpiperidine, and N-acetylpyrrolidine. These amide-based solvents may be used singly or in combination of two or more kinds thereof.

Examples of the ester-based solvent may include diethyl carbonate, ethylene carbonate, propylene carbonate, diethyl carbonate, methyl acetate, ethyl acetate, γ-butyrolactone, γ-valerolactone, n-propyl acetate, isopropyl acetate, n-butyl acetate, isobutyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate. These ester-based solvents may be used singly or in combination of two or more kinds thereof.

Examples of the aprotic solvents may include acetonitrile, dimethyl sulfoxide, N,N,N′,N′-tetraethyl sulfamide, hexamethylphosphoric triamide, N-methylmorpholine, N-methylpyrrole, N-ethylpyrrole, N-methylpiperidine, N-ethylpiperidine, N,N-dimethylpiperazine, N-methylimidazole, N-methyl-4-piperidone, N-methyl-2-piperidone, N-methyl-2-pyrrolidone, 1,3-dimethyl-2-imidazolidinone, and 1,3-dimethyltetrahydro-2(1H)-pyrimidinone. The organic solvents described above may be used singly or in combination of two or more kinds thereof.

In the present invention, as the organic solvent used in the formation of the intermediate layer, an alcohol-based solvent is preferable among the above organic solvents.

Examples of the method for coating the coating liquid for intermediate layer formation may include a spin coating method, a dipping method, a roller blade method, and a spray method.

The film thickness of the intermediate layer that is formed by the coating liquid for intermediate layer formation is preferably set to be in a range of 100 nm to 10 μm. It is possible to secure the gas barrier property at a high humidity when the film thickness of the intermediate layer is 100 nm or more. In addition, it is possible to obtain stable coatability at the time of forming the intermediate layer and to realize a high light transmitting property when the film thickness of the intermediate layer is 10 μm or less.

In addition, the film density of the intermediate layer is usually from 0.35 to 1.2 g/cm³, preferably from 0.4 to 1.1 g/cm³, and more preferably from 0.5 to 1.0 g/cm³. It is possible to obtain a sufficient mechanical strength as a coating film when the film density is 0.35 g/cm³ or more.

As vacuum ultraviolet light used for the formation of this intermediate layer, it is possible to apply the same vacuum ultraviolet light in the vacuum ultraviolet light irradiation treatment as that described in the formation of the gas barrier layer.

In addition, in the present invention, the integrated light quantity of vacuum ultraviolet light when forming the intermediate layer by modifying the polysiloxane film is preferably 500 mJ/cm² or more and 10,000 mJ/cm² or less. It is possible to obtain sufficient barrier performance when the integrated light quantity of vacuum ultraviolet light is 500 mJ/cm² or more, and it is possible to form an intermediate layer exhibiting high smoothness without deformation of the substrate when it is 10,000 mJ/cm² or less.

In addition, it is preferable that the intermediate layer of the present invention is formed through the heating step conducted at a heating temperature of 50° C. or higher and 200° C. or lower. It is possible to obtain sufficient barrier property when the heating temperature is 50° C. or higher, and it is possible to form an intermediate layer exhibiting high smoothness without deformation of the substrate when it is 200° C. or lower. In this heating step, it is possible to apply a heating method to use a hot plate, an oven, a furnace, and the like. In addition, the heating atmosphere may be any condition of an air atmosphere, a nitrogen atmosphere, an argon atmosphere, a vacuum atmosphere, or a reduced pressure having a controlled concentration of oxygen.

Incidentally, the intermediate layer has a function to cover the gas barrier layer so as to prevent the gas barrier layer in the gas barrier film from being damaged, but the intermediate layer can also prevent the gas barrier layer from being damaged in the producing process of the gas barrier film.

The method for forming the intermediate layer is not particularly limited, and for example, when forming the gas barrier layer, a polysiloxane coating layer is formed on a coating layer containing a polysilazane that is formed but not modified, and the polysilazane coating layer and the polysiloxane coating layer are simultaneously irradiated with vacuum ultraviolet light and then subjected to the heating treatment at 100° C. or higher and 250° C. or lower, whereby the gas barrier layer and the intermediate layer are formed. In addition, a polysiloxane coating layer is formed on the polysilazane coating film layer subjected to the vacuum ultraviolet light irradiation treatment, the polysiloxane coating layer is subjected to the vacuum ultraviolet light irradiation treatment and then subjected to the heating treatment at 100° C. or higher and 250° C. or lower, whereby the gas barrier layer that is formed by coating a solution containing a polysilazane compound and the intermediate layer are formed.

As described above, in the case of conducting the heating treatment at 100° C. or higher, in a state that the coating layer formed by coating a solution containing a polysilazane compound is covered with the intermediate layer (polysiloxane coating film), it is possible to prevent the gas barrier layer from being finely fissured by the thermal stress due to the heating treatment, and thus it is possible to stabilize the water vapor barrier performance of the gas barrier layer.

[Protective Layer]

In the gas barrier film according to the present invention, a protective layer containing an organic compound may be provided on top of the gas barrier layer formed by coating or the gas barrier layer formed by a deposition method. As the organic compound used in the protective layer, it is possible to preferably use an organic resin such as an organic monomer, an organic oligomer, and an organic polymer and an organic and inorganic composite resin using a monomer, an oligomer, a polymer, and the like of a siloxane or silsesquioxane having an organic group. It is preferable that these organic resins or organic and inorganic composite resins have a polymerizable group or a crosslinkable group, and it is preferable that a layer that is formed by coating a coating liquid of an organic resin composition containing these organic resins or organic and inorganic composite resins, and if necessary, a polymerization initiator, a crosslinking agent, or the like is cured by adding the light irradiation treatment or the heat treatment. Here, the “crosslinkable group” refers to a group capable of crosslinking the binder polymer by a chemical reaction occurring in the light irradiation treatment or the heat treatment. The chemical structure thereof is not particularly limited as long as it is a group having such a function, but examples thereof as a functional group capable of being used in addition polymerization may include an ethylenically unsaturated group and a cyclic ether group such as an epoxy group/an oxetanyl group. In addition, it may be a functional group capable of forming a radical by being irradiated with light, and examples of such a crosslinkable group may include a thiol group, a halogen atom, and an onium salt structure. Among them, an ethylenically unsaturated group is preferable, and the functional groups described in the paragraphs “0130” to “0139” of JP 2007-17948 A are included.

As the organic and inorganic composite resin, for example, the organic and inorganic composite resin described as the “ORMOCER (registered trademark)” in U.S. Pat. No. 6,503,634 can be preferably used.

It is possible to adjust the elastic modulus of the protective layer to a desired value by appropriately adjusting the structure of the organic resin or the density of the polymerizable group, the density of the crosslinkable group, the ratio of the crosslinking agent, the curing condition, and the like.

Specific examples of the organic resin composition may include a resin composition containing a (meth)acrylate compound having a radical reactive unsaturated compound, a resin composition containing a (meth)acrylate compound and a mercapto compound having a thiol group, and a resin composition obtained by dissolving a polyfunctional (meth)acrylate monomer such as an epoxy (meth)acrylate, a urethane (meth)acrylate, a polyester (meth)acrylate, a polyether (meth)acrylate, polyethylene glycol (meth)acrylate, or glycerol (meth)acrylate. In addition, it is also possible to use an arbitrary mixture of resin compositions as mentioned above, and it is not particularly limited as long as it is a photosensitive resin containing a reactive monomer having one or more photopolymerizable unsaturated bonds in the molecule.

Examples of the reactive monomer having one or more photopolymerizable unsaturated bonds in the molecule may include methyl acrylate, ethyl acrylate, n-propyl acrylate, isopropyl acrylate, n-butyl acrylate, isobutyl acrylate, tert-butyl acrylate, n-pentyl acrylate, n-hexyl acrylate, 2-ethylhexyl acrylate, n-octyl acrylate, n-decyl acrylate, hydroxyethyl acrylate, hydroxypropyl acrylate, allyl acrylate, benzyl acrylate, butoxyethyl acrylate, butoxy ethylene glycol acrylate, cyclohexyl acrylate, dicyclopentanyl acrylate, 2-ethylhexyl acrylate, glycerol acrylate, glycidyl acrylate, 2-hydroxyethyl acrylate, 2-hydroxypropyl acrylate, isobornyl acrylate, isodecyl acrylate, isooctyl acrylate, lauryl acrylate, 2-methoxyethyl acrylate, methoxy ethylene glycol acrylate, phenoxyethyl acrylate, stearyl acrylate, ethylene glycol diacrylate, diethylene glycol diacrylate, 1,4-butanediol diacrylate, 1,5-pentanediol diacrylate, 1,6-hexanediol diacrylate, 1,3-propanediol diacrylate, 1,4-cyclohexanediol diacrylate, 2,2-dimethylolpropane diacrylate, glycerol diacrylate, tripropylene glycol diacrylate, glycerol triacrylate, trimethylolpropane triacrylate, polyoxyethyl trimethylolpropane triacrylate, pentaerythritol triacrylate, pentaerythritol tetraacrylate, ethylene oxide-modified pentaerythritol triacrylate, ethylene oxide-modified pentaerythritol tetraacrylate, propylene oxide-modified pentaerythritol triacrylate, propylene oxide-modified pentaerythritol tetraacrylate, triethylene glycol diacrylate, polyoxypropyl trimethylolpropane triacrylate, butylene glycol diacrylate, 1,2,4-butanediol triacrylate, 2,2,4-trimethyl-1,3-pentanediol diacrylate, diallyl fumarate, 1,10-decanediol dimethylacrylate, pentaerythritol hexaacrylate, those obtained by substituting above-mentioned acrylate with methacrylate, γ-methacryloxypropyltrimethoxysilane, and 1-vinyl-2-pyrrolidone. The above reactive monomers can be used singly, as a mixture of two or more kinds thereof, or a mixture with other compounds.

The composition of a photosensitive resin contains a photopolymerization initiator. Examples of the photopolymerization initiator may include benzophenone, methyl o-benzoyl benzoate, 4,4-bis(dimethylamine)benzophenone, 4,4-bis(diethylamine)benzophenone, α-aminoacetophenone, 4,4-dichlorobenzophenone, 4-benzoyl-4-methyl diphenyl ketone, dibenzyl ketone, fluorenone, 2,2-diethoxyacetophenone, 2,2-dimethoxy-2-phenylacetophenone, 2-hydroxy-2-methylpropiophenone, p-tert-butyldichloroacetophenone, thioxanthone, 2-methylthioxanthone, 2-chlorothioxanthone, 2-isopropylthioxanthone, diethylthioxanthone, benzyl dimethyl ketal, benzyl methoxyethyl acetal, benzoin methyl ether, benzoin butyl ether, anthraquinone, 2-tert-butylanthraquinone, 2-amylanthraquinone, β-chloroanthraquinone, anthrone, benzanthrone, dibenzosuberone, methyleneanthrone, 4-azidobenzylacetophenone, 2,6-bis(p-azidobenzylidene)cyclohexane, 2,6-bis(p-azidobenzylidene)-4-methylcyclohexanone, 2-phenyl-1,2-butadione-2-(o-methoxycarbonyl)oxime, 1-phenyl-propanedione-2-(o-ethoxycarbonyl)oxime, 1,3-diphenyl-propanetrione-2-(o-ethoxycarbonyl)oxime, 1-phenyl-3-ethoxy-propanetrione-2-(o-benzoyl)oxime, Michler's ketone, 2-methyl[4-(methylthio)phenyl]-2-morpholino-1-propane, 2-benzyl-2-dimethylamino-1-(4-morpholinophenyl)-butanone-1, naphthalenesulfonyl chloride, quinoline sulfonyl chloride, n-phenylthioacridone, 4,4-azobisisobutyronitrile, diphenyl disulfide, benzothiazole disulfide, triphenylphosphine, camphorquinone, carbon tetrabromide, tribromophenylsulfone, benzoyl peroxide, and a combination of a light reducing dye such as eosin or methylene blue and a reducing agent such as ascorbic acid or triethanolamine, and these photopolymerization initiator can be used singly or in combination of two or more kinds thereof.

It is possible to contain an inorganic material in the protective layer. The elastic modulus of the protective layer generally increases as an inorganic material is contained. It is possible to adjust the elastic modulus of the protective layer to a desired value by appropriately adjusting the content ratio of the inorganic material.

As the inorganic material, inorganic fine particles having a number average particle size of from 1 to 200 nm are preferable and inorganic fine particles having a number average particle size of from 3 to 100 nm are more preferable. As the inorganic fine particles, a metal oxide is preferable from the viewpoint of transparency.

The metal oxide is not particularly limited, but examples thereof may include SiO₂, Al₂O₃, TiO₂, ZrO₂, ZnO, SnO₂, In₂O₃, BaO, SrO, CaO, MgO, VO₂, V₂O₅, CrO₂, MoO₂, MoO₃, MnO₂, Mn₂O₃, WO₃, LiMn₂O₄, Cd₂SnO₄, CdIn₂O₄, Zn₂SnO₄, ZnSnO₃, Zn₂In₂O₅, Cd₂SnO₄, CdIn₂O₄, Zn₂SnO₄, ZnSnO₃, and Zn₂In₂O₅. These may be used as a single body or two or more kinds thereof may be used concurrently.

In order to obtain a dispersion of inorganic fine particles, the dispersion may be prepared in accordance with a recent scientific treatise, but a commercially available inorganic fine particle dispersion can also be preferably used.

Specific examples thereof may include dispersions of various metal oxides such as the SNOWTEX (registered trademark) series or ORGANOSILICASOL manufactured by NISSAN CHEMICAL INDUSTRIES, LTD., the NANOBYK (registered trademark) series manufactured by BYK Japan KK, and the NanoDur (registered trademark) manufactured by Nanophase Technologies Corporation.

These inorganic fine particles may be those which have been subjected to the surface treatment.

As the inorganic material, it is also possible to use plate-shaped fine particles such as a mica group including natural mica and synthetic mica, talc represented by Formula 3MgO.4SiO.H₂O, taeniolite, montmorillonite, saponite, hectorite, and zirconium phosphate.

Specifically, examples of the natural mica may include white mica, soda mica, phlogopite, biotite, and lepidolite. In addition, examples of the synthetic mica may include non-swelling mica such as potassium fluorphlogopite KMg₃(AlSi₃O₁₀)F₂ potassium-tetrasilic mica KMg_{2.5}(Si₄O₁₀)F₂ and the like, and swelling mica such as Na tetrasilylic mica NaMg_{2.5}(Si₄O₁₀)F₂, Na or Li taeniolite (Na or Li) Mg₂Li(Si₄O₁₀)F₂ and montmorillonite-based Na or Li hectorite (Na or Li)_{1/8}Mg_{2/5}Li_{1/8}(Si₄O₁₀)F₂. In addition, synthetic smectite is also useful.

The ratio of the inorganic material in the protective layer is set to be in a range of preferably from 10 to 95% by mass and more preferably from 20 to 90% by mass with respect to the entire protective layer.

In the protective layer, a so-called coupling agent may be used singly or as a mixture with other materials. The coupling agent is not particularly limited, but examples thereof may include a silane coupling agent, a titanate-based coupling agent, and an aluminate-based coupling agent, and a silane coupling agent is preferable from the viewpoint of stability of the coating liquid.

Specific examples of the silane coupling agent may include a halogen-containing silane coupling agent (2-chloroethyltrimethoxysilane, 2-chloroethyltriethoxysilane, 3-chloropropyltrimethoxysilane, 3-chloropropyltriethoxysilane, and the like), an epoxy group-containing silane coupling agent [2-(3,4-epoxycyclohexyl) ethyltrimethoxysilane, 2-(3,4-epoxycyclohexyl) ethyltriethoxysilane, 3-(3,4-epoxycyclohexyl) propyltrimethoxysilane, 2-glycidyloxyethyltrimethoxysilane, 2-glycidyloxyethyltriethoxysilane, 3-glycidyloxypropyltrimethoxysilane, 3-glycidyloxypropyltriethoxysilane, and the like], an amino group-containing silane coupling agent (2-aminoethyltrimethoxysilane, 3-aminopropyltrimethoxysilane, 3-aminopropyltriethoxysilane, 2-[N-(2-aminoethyl)amino]ethyltrimethoxysilane, 3-[N-(2-aminoethyl)amino]propyltrimethoxysilane, 3-(2-aminoethyl)amino]propyltriethoxysilane, 3-[N-(2-aminoethyl)amino]propylmethyldimethoxysilane, and the like), a mercapto group-containing silane coupling agent (2-mercaptoethyltrimethoxysilane, 3-mercaptopropyltrimethoxysilane, 3-mercaptopropyltriethoxy silane, and the like), a vinyl group-containing silane coupling agent (vinyltrimethoxysilane, vinyltriethoxysilane, and the like), and a (meth)acryloyl group-containing silane coupling agent (2-methacryloyloxyethyltrimethoxysilane, 2-methacryloyloxyethyltriethoxysilane, 2-acryloyloxyethyltrimethoxysilane, 3-methacryloyloxypropyltrimethoxysilane, 3-methacryloyloxypropyltriethoxysilane, 3-acryloyloxypropyltrimethoxysilane, and the like). These silane coupling agents can be used singly or in combination of two or more kinds thereof.

It is preferable to form the protective layer by blending the organic resin or the inorganic material, and if necessary, other components together, appropriately diluting the mixture with a diluting solvent to be used if necessary to prepare a coating liquid, coating the coating liquid on the surface of the substrate by a coating method known in the prior art, and then irradiating the coating film with ionizing radiation to cure it. Incidentally, as the method for irradiating the coating film with ionizing radiation, the coating film is irradiated with ultraviolet rays in a wavelength region of from 100 to 400 nm preferably from 200 to 400 nm emitted from an ultra-high pressure mercury lamp, a high pressure mercury lamp, a low pressure mercury lamp, a carbon arc, a metal halide lamp, or the like. Alternatively, the curing can be conducted by irradiating the coating film with an electron beam in a wavelength region of 100 nm or less emitted from an electron beam accelerator of a scanning type or a curtain type.

In addition, the protective layer can also be cured through vacuum ultraviolet ray irradiation using the excimer lamp described above. It is preferable that curing of the protective layer is also conducted through vacuum ultraviolet ray irradiation using an excimer lamp in the case of coating and forming the gas barrier layer and the protective layer in the same line.

In addition, in a case in which an alkoxy-modified polysiloxane coating film is formed on the coated layer that is a gas barrier layer formed by coating a solution containing a polysilazane compound and is not subjected to the modification treatment, and the resultant is irradiated with vacuum ultraviolet rays from above, the alkoxy-modified polysiloxane coating film becomes a protective layer and further the modification of the polysilazane coating layer of the lower layer can also be conducted, and thus it is possible to obtain a gas barrier layer which exhibits superior storage stability at a high temperature and a high humidity.

In addition, as the method for forming the protective layer, it is possible to apply the method for forming the polysiloxane-modified layer of the intermediate layer.

[Desiccant Layer]

The gas barrier film of the present invention may include a desiccant layer (moisture adsorbing layer). Examples of the material used as the desiccant layer may include calcium oxide or an organic metal oxide. As calcium oxide, those which are dispersed in a binder resin and the like are preferable, and as a commercially available product thereof, for example, the AqvaDry series manufactured by SAES Getters can be preferably used. In addition, as the organic metal oxide, for example, the OleDry (registered trademark) series manufactured by Futaba Corporation, and the like can be used.

[Smoothing Layer (Base Layer, Primer Layer, Hard Coat Layer)]

The gas barrier film of the present invention may include a smoothing layer (base layer, primer layer, hard coat layer) on the surface having a gas barrier layer of the substrate, and preferably between the substrate and the first gas barrier layer. The smoothing layer is provided in order to flatten the rough surface of the substrate having protrusions and the like or to fill and flatten the concave and convex or pinholes generated on the gas barrier layer by the protrusions present on the substrate. Such a smoothing layer may be formed by any material, but it is preferable that the smoothing layer contains a carbon-containing polymer and it is more preferable that the smoothing layer is composed of a carbon-containing polymer. In other words, it is preferable that the gas barrier film of the present invention further includes a smoothing layer containing a carbon-containing polymer between the substrate and the first gas barrier layer.

In addition, the smoothing layer contains a carbon-containing polymer and preferably a curable resin. The curable resin is not particularly limited, and examples thereof may include an active energy ray curable resin obtained by irradiating an active energy ray-curable material and the like with an active energy ray such as ultraviolet rays to cure it and a thermosetting resin obtained by heating a thermosetting material to cure it. The curable resins may be used singly or in combination of two or more kinds thereof.

Examples of the active energy ray curable material used in the formation of the smoothing layer may include a composition containing a (meth)acrylate compound, a composition containing a (meth)acrylate compound and a mercapto compound containing a thiol group, and a composition containing a polyfunctional(meth)acrylate monomer such as an epoxy (meth)acrylate, a urethane (meth)acrylate, a polyester (meth)acrylate, a polyether (meth)acrylate, polyethylene glycol (meth)acrylate, or glycerol (meth)acrylate. Specifically, it is possible to use the organic/inorganic hybrid hard coat material OPSTAR (registered trademark) series (compound obtained by bonding an organic compound having a polymerizable unsaturated group to silica fine particles) of an ultraviolet curable material manufactured by JSR Corporation. In addition, it is also possible to use an arbitrary mixture of compositions as mentioned above, and it is not particularly limited as long as it is an active energy ray curable material containing a reactive monomer having one or more photopolymerizable unsaturated bonds in the molecule.

Examples of the reactive monomer having one or more photopolymerizable unsaturated bonds in the molecule may include methyl acrylate, ethyl acrylate, n-propyl acrylate, isopropyl acrylate, n-butyl acrylate, isobutyl acrylate, tert-butyl acrylate, n-pentyl acrylate, n-hexyl acrylate, 2-ethylhexyl acrylate, n-octyl acrylate, n-decyl acrylate, hydroxyethyl P [symbol] ω̅ [symbol] ç [symbol] W [symbol] ropyl acrylate, allyl acrylate, benzyl acrylate, butoxyethyl acrylate, butoxy ethylene glycol acrylate, cyclohexyl acrylate, dicyclopentanyl acrylate, 2-ethylhexyl acrylate, glycerol acrylate, glycidyl acrylate, 2-hydroxyethyl acrylate, 2-hydroxypropyl acrylate, isobornyl acrylate, isodecyl acrylate, isooctyl acrylate, lauryl acrylate, 2-methoxyethyl acrylate, methoxy ethylene glycol acrylate, phenoxyethyl acrylate, stearyl acrylate, ethylene glycol diacrylate, diethylene glycol diacrylate, 1,4-butanediol diacrylate, 1,5-pentanediol diacrylate, 1,6-hexanediol diacrylate, 1,3-propanediol diacrylate, 1,4-cyclohexanediol diacrylate, 2,2-dimethylolpropane diacrylate, glycerol diacrylate, tripropylene glycol diacrylate, glycerol triacrylate, trimethylolpropane triacrylate, polyoxyethyl trimethylolpropane triacrylate, pentaerythritol triacrylate, pentaerythritol tetraacrylate, ethylene oxide-modified pentaerythritol triacrylate, ethylene oxide-modified pentaerythritol tetraacrylate, propylene oxide-modified pentaerythritol triacrylate, propylene oxide-modified pentaerythritol tetraacrylate, triethylene glycol diacrylate, polyoxypropyl trimethylolpropane triacrylate, butylene glycol diacrylate, 1,2,4-butanediol triacrylate, 2,2,4-trimethyl-1,3-pentanediol diacrylate, diallyl fumarate, 1,10-decanediol dimethylacrylate, pentaerythritolhexaacrylate, those obtained by substituting above-mentioned acrylate with methacrylate, γ-methacryloxypropyltrimethoxysilane, and 1-vinyl-2-pyrrolidone. The above reactive monomers can be used singly, as a mixture of two or more kinds thereof or a mixture with other compounds.

The composition containing an active energy ray curable material preferably contains a photopolymerization initiator.

Examples of the photopolymerization initiator may include benzophenone, methyl o-benzoyl benzoate, 4,4-bis(dimethylamine)benzophenone, 4,4-bis(diethylamine)benzophenone, α-aminoacetophenone, 4,4-dichlorobenzophenone, 4-benzoyl-4-methyl diphenyl ketone, dibenzyl ketone, fluorenone, 2,2-diethoxyacetophenone, 2,2-dimethoxy-2-phenylacetophenone, 2-hydroxy-2-methylpropiophenone, p-tert-butyldichloroacetophenone, thioxanthone, 2-methylthioxanthone, 2-chlorothioxanthone, 2-isopropylthioxanthone, diethylthioxanthone, benzyl dimethyl ketal, benzyl methoxyethyl acetal, benzoin methyl ether, benzoin butyl ether, anthraquinone, 2-tert-butylanthraquinone, 2-amylanthraquinone, β-chloroanthraquinone, anthrone, benzanthrone, dibenzosuberone, methyleneanthrone, 4-azidobenzylacetophenone, 2,6-bis(p-azidobenzylidene)cyclohexane, 2,6-bis(p-azidobenzylidene)-4-methylcyclohexanone, 2-phenyl-1,2-butadione-2-(o-methoxycarbonyl)oxime, 1-phenyl-propanedione-2-(o-ethoxycarbonyl)oxime, 1,3-diphenyl-propanetrione-2-(o-ethoxycarbonyl)oxime, 1-phenyl-3-ethoxy-propanetrione-2-(o-benzoyl)oxime, Michler's ketone, 2-methyl[4-(methylthio)phenyl]-2-morpholino-1-propane, 2-benzyl-2-dimethylamino-1-(4-morpholinophenyl)-butanone-1, naphthalenesulfonyl chloride, quinoline sulfonyl chloride, n-phenylthioacridone, 4,4-azobisisobutyronitrile, diphenyl disulfide, benzothiazole disulfide, triphenylphosphine, camphorquinone, carbon tetrabromide, tribromophenylsulfone, benzoyl peroxide, and a combination of a light reducing dye such as eosin or methylene blue and a reducing agent such as ascorbic acid or triethanolamine, and these photopolymerization initiator can be used singly or in combination of two or more kinds thereof.

Specific examples of the thermosetting material may include the TutoProm (organic polysilazane) series manufactured by Clariant, SP COAT of a heat resistant clear coating material manufactured by CERAMIC COAT CO., LTD., the Nano-Hybrid Silicone manufactured by ADEKA CORPORATION, the UNIDIC (registered trademark) V-8000 Series and the EPICLON (registered trademark) EXA-4710 (ultra-high heat resistant epoxy resin) manufactured by DIC Corporation, the silicon resin X-12-2400 (trade name) manufactured by Shin-Etsu Chemical Co., Ltd., the inorganic and organic nanocomposite material SSG Coat manufactured by Nitto Boseki Co., Ltd., a thermosetting urethane resin composed of an acrylic polyol and an isocyanate prepolymer, a phenolic resin, a urea melamine resin, an epoxy resin, an unsaturated polyester resin, a silicone resin, and a polyamide amine-epichlorohydrin resin.

The method for forming the smoothing layer is not particularly limited, but a method is preferable in which a coating liquid containing a curable material is coated by a wet coating method such as a spin coating method, a spray method, a blade coating method, a dipping method, or a gravure printing method or a dry coating method such as a deposition method to form a coating film and the coating film is then irradiated with an active energy ray such as visible light, infrared rays, ultraviolet rays, X-rays, α rays, β rays, γ rays, or electron beams and/or heated to be cured, whereby the smoothing layer is formed. Examples of the method for irradiating the coating film with an active energy ray, a method in which the coating film is irradiated with ultraviolet rays in a wavelength region of preferably from 100 to 400 nm and more preferably from 200 to 400 nm using an ultra-high pressure mercury lamp, a high pressure mercury lamp, a low pressure mercury lamp, a carbon arc, a metal halide lamp, or the like or the coating film is irradiated with an electron beam in a wavelength region of 100 nm or less emitted from an electron beam accelerator of a scanning type or a curtain type.

Examples of the solvent used when forming the smoothing layer using a coating liquid that is prepared by dissolving or dispersing the curable material in a solvent may include an alcohol such as methanol, ethanol, n-propyl alcohol, isopropyl alcohol, ethylene glycol, or propylene glycol, a terpene such as α- or β-terpineol, a ketone such as acetone, methyl ethyl ketone, cyclohexanone, N-methyl-2-pyrrolidone, diethyl ketone, 2-heptanone, or 4-heptanone, an aromatic hydrocarbon such as toluene, xylene, or tetramethylbenzene, a glycol ether such as cellosolve, methyl cellosolve, ethyl cellosolve, carbitol, methyl carbitol, ethyl carbitol, butyl carbitol, propylene glycol monomethyl ether, propylene glycol monoethyl ether, dipropylene glycol monomethyl ether, dipropylene glycol monoethyl ether, triethylene glycol monomethyl ether, or triethylene glycol monoethyl ether, an acetic acid ester such as ethyl acetate, butyl acetate, cellosolve acetate, ethyl cellosolve acetate, butyl cellosolve acetate, carbitol acetate, ethyl carbitol acetate, butyl carbitol acetate, propylene glycol monomethyl ether acetate, propylene glycol monoethyl ether acetate, 2-methoxyethyl acetate, cyclohexyl acetate, 2-ethoxyethyl acetate, or 3-methoxybutyl acetate, diethylene glycol dialkyl ether, dipropylene glycol dialkyl ether, ethyl 3-ethoxypropionate, methyl benzoate, N,N-dimethylacetamide, and N,N-dimethylformamide.

The smoothing layer can contain a thermoplastic resin or additives such as an antioxidant, an ultraviolet absorber, and a plasticizer if necessary in addition to the materials described above. In addition, a proper resin and an additive may be used in order to improve film formability and to prevent the generation of pinholes on the film. Examples of the thermoplastic resin may include a cellulose derivative such as acetyl cellulose, nitrocellulose, acetyl butyl cellulose, ethyl cellulose, or methyl cellulose, a vinyl resin such as vinyl acetate and its copolymers, vinyl chloride and its copolymers, or vinylidene chloride and its copolymers, an acetal resin such as polyvinyl formal or polyvinyl butyral, an acrylic resin such as an acrylic resin and its copolymers or a methacrylic resin and its copolymers, a polystyrene resin, a polyamide resin, a linear polyester resin, and a polycarbonate resin.

As the smoothness of the smoothing layer, it is preferable that the maximum section height Rt (p) is 10 nm or more and 30 nm or less as the value represented by the surface roughness that is defined in JIS B 0601: 2001.

The surface roughness is calculated from the sectional curve of the concave and convex that is continuously measured by the detector having a stylus with the minimum tip radius using an AFM (atomic force microscope), is measured several times within a section of tens μm in the measurement direction by the stylus with the minimum tip radius, and is a roughness on the amplitude of fine concave and convex.

The film thickness of the smoothing layer is not particularly limited, but it is preferably set to be in a range of from 0.1 to 10 μm.

[Anchor Coat Layer]

An anchor coat layer may be formed on the surface of the substrate as an adhesion promoting layer for the purpose of improving adhesiveness (adhesive property). As the anchor coating agent used in this anchor coat layer, it is possible to use a polyester resin, an isocyanate resin, a urethane resin, an acrylic resin, an ethylene and vinyl alcohol resin, a vinyl-modified resin, an epoxy resin, a modified styrene resin, a modified silicone resin, an alkyl titanate, and the like singly, or two or more kinds thereof can be used concurrently. As the anchor coating agent, a commercially available product may be used. Specifically, a siloxane-based UV-curable polymer solution (3% isopropyl alcohol solution of “X-12-2400” manufactured by Shin-Etsu Chemical Co., Ltd.) can be used.

It is possible to add an additive known in the prior art to these anchor coating agents. In addition, the above anchor coating agent can be coated by coating it on the substrate by a known method such as roll coating, gravure coating, knife coating, dip coating, or spray coating and then removing the solvent, the diluent, and the like through drying. The coating amount of the above anchor coating agent is preferably about from 0.1 to 5 g/m² (dried state). Incidentally, a commercially available substrate with adhesion promoting layer may be used.

Alternatively, the anchor coat layer can also be formed by a vapor phase method such as a physical deposition method or a chemical deposition method. For example, it is also possible to form an inorganic film containing silicon oxide as the main component for the purpose of improving adhesiveness and the like as described in JP-A No. 2008-142941.

In addition, the thickness of the anchor coat layer is not particularly limited, but it is preferably about from 0.5 to 10.0 μm.

[Bleed-Out Preventing Layer]

The gas barrier film of the present invention may include a bleed-out preventing layer on the substrate surface on the side opposite to the surface provided with the gas barrier layer.

The bleed-out preventing layer is provided for the purpose of suppressing a phenomenon that the unreacted oligomer and the like migrate from the inside of the film to the surface when heating the film and contaminate the surface that comes in contact with them. The bleed-out preventing layer may basically have the same configuration as the smoothing layer as long as it has this function.

Examples of the unsaturated organic compound having a polymerizable unsaturated group that can be contained as a hard coat agent in the bleed-out preventing layer may include a polyvalent unsaturated organic compound having two or more polymerizable unsaturated groups in the molecule or a monovalent unsaturated organic compound having one polymerizable unsaturated group in the molecule.

Here, examples of the polyvalent unsaturated organic compound may include ethylene glycol di(meth)acrylate, diethylene glycol di(meth)acrylate, glycerol di(meth)acrylate, glycerol tri(meth)acrylate, 1,4-butanediol di(meth)acrylate, 1,6-hexanediol di(meth)acrylate, neopentyl glycol di(meth)acrylate, trimethylolpropane tri(meth)acrylate, dicyclopentanyl di(meth)acrylate, pentaerythritol tri(meth)acrylate, pentaerythritol tetra(meth)acrylate, dipentaerythritol hexa(meth)acrylate, dipentaerythritol monohydroxy penta(meth)acrylate, ditrimethylolpropane tetra(meth)acrylate, diethylene glycol di(meth)acrylate, polyethylene glycol di(meth)acrylate, tripropylene glycol di(meth)acrylate, and polypropylene glycol di(meth)acrylate.

In addition, examples of the monovalent unsaturated organic compound may include methyl (meth)acrylate, ethyl (meth)acrylate, propyl (meth)acrylate, butyl (meth)acrylate, 2-ethylhexyl (meth)acrylate, isodecyl (meth)acrylate, lauryl (meth)acrylate, stearyl (meth)acrylate, allyl (meth)acrylate, cyclohexyl (meth)acrylate, methylcyclohexyl (meth)acrylate, isobornyl (meth)acrylate, 2-hydroxyethyl (meth)acrylate, 2-hydroxypropyl (meth)acrylate, glycerol (meth)acrylate, glycidyl (meth)acrylate, benzyl (meth)acrylate, 2-ethoxyethyl (meth)acrylate, 2-(2-ethoxyethoxy)ethyl (meth)acrylate, butoxyethyl (meth)acrylate, 2-methoxyethyl (meth)acrylate, methoxy diethylene glycol (meth)acrylate, methoxy triethylene glycol (meth)acrylate, methoxypolyethylene glycol (meth)acrylate, 2-methoxypropyl (meth)acrylate, methoxy dipropylene glycol (meth)acrylate, methoxy tripropylene glycol (meth)acrylate, methoxy polypropylene glycol (meth)acrylate, polyethylene glycol (meth)acrylate, and polypropylene glycol (meth)acrylate.

As other additives, a matting agent may be contained. Inorganic particles having an average particle size of about from 0.1 to 5 μm is preferable as the matting agent. As such inorganic particles, it is possible to use silica, alumina, talc, clay, calcium carbonate, magnesium carbonate, barium sulfate, aluminum hydroxide, titanium dioxide, and zirconium oxide singly, or two or more kinds thereof can be used concurrently.

Here, it is desirable that the matting agent composed of the inorganic particles is mixed with the hard coat agent at a proportion of 2 parts by mass or more, preferably 4 parts by mass or more, and more preferably 6 parts by mass or more and 20 parts by mass or less, preferably 18 parts by mass or less, and more preferably 16 parts by mass or less with respect to 100 parts by mass of the solid content of the hard coat agent.

In addition, the bleed-out preventing layer may contain thermoplastic resin, a thermosetting resin, an ionizing radiation curable resin, a photopolymerization initiator, and the like as the component other than the hard coat agent and the matting agent.

Examples of such a thermoplastic resin may include a cellulose derivative such as acetyl cellulose, nitrocellulose, acetyl butyl cellulose, ethyl cellulose, or methyl cellulose, a vinyl-based resin such as vinyl acetate and its copolymers, vinyl chloride and its copolymers, or vinylidene chloride and its copolymers, an acetal-based resin such as polyvinyl formal or polyvinyl butyral, an acrylic resin such as an acrylic resin and its copolymers or a methacrylic resin and its copolymers, a polystyrene resin, a polyamide resin, a linear polyester resin, and a polycarbonate resin.

In addition, examples of the thermosetting resin may include a thermosetting urethane resin composed of a (meth) acrylic polyol and an isocyanate prepolymer, a phenolic resin, a urea melamine resin, an epoxy resin, an unsaturated polyester resin, and a silicone resin.

In addition, as the ionizing radiation curable resin, those which are obtained by irradiating the ionizing radiation curable coating material of one kind or a mixture of two or more kinds of a photopolymerizable prepolymer, a photopolymerizable monomer, and the like with ionizing radiation (ultraviolet rays or electron beam) to cure it can be used. Here, as the photopolymerizable prepolymer, a (meth)acrylic prepolymer which has two or more (meth)acryloyl groups in one molecule and forms a three-dimensional network structure by being crosslinked and cured is even more preferably used. As this (meth)acrylic prepolymer, a urethane (meth)acrylate, a polyester (meth)acrylate, an epoxy (meth)acrylate, a melamine (meth)acrylate, and the like can be used. In addition, as the photopolymerizable monomer, the polyvalent unsaturated organic compounds described above can be used.

In addition, examples of the photopolymerization initiator may include acetophenone, benzophenone, Michler's ketone, benzoin, benzil methyl ketal, benzoin benzoate, hydroxycyclohexyl phenyl ketone, 2-methyl-1-(4-(methylthio)phenyl)-2-(4-morpholinyl)-1-propane, α-acyloxime ester, and a thioxanthone.

The bleed-out preventing layer as above can be formed by blending a hard coat agent, a matting agent, and if necessary other components together, appropriately diluting the mixture with a diluting solvent to be used if necessary to prepare a coating liquid, coating the coating liquid on the surface of the supporting film by a coating method known in the prior art, and then irradiating the coating film with ionizing radiation to cure it.

Incidentally, as the method for irradiating the coating film with ionizing radiation, the coating film is irradiated with ultraviolet rays in a wavelength region of from 100 to 400 nm preferably from 200 to 400 nm emitted from an ultra-high pressure mercury lamp, a high pressure mercury lamp, a low pressure mercury lamp, a carbon arc, a metal halide lamp, or the like, or the curing can be conducted by irradiating the coating film with an electron beam in a wavelength region of 100 nm or less emitted from an electron beam accelerator of a scanning type or a curtain type.

The thickness of the bleed-out preventing layer is set to be in a range of preferably from 1.0 to 10 μm and even more preferably from 2 to 7 μm from the viewpoint of improving the heat resistance of the film, facilitating the adjustment of the balance of the optical properties of the film, and adjusting the curling of the gas barrier film.

<<Packing State of Gas Barrier Film>>

The gas barrier film of the present invention can be continuously produced and wound into a roll form (so-called roll-to-roll production). At that time, it is preferable to paste a protective sheet on the surface on which the gas barrier layer is formed and to wind it. In particular, in the case of using the gas barrier film of the present invention as a sealing material for an organic thin film device, a defect is caused by the dust (for example, particles) attached to the surface in many cases, and thus it is significantly effective to prevent the attachment of dust by pasting a protective sheet at a place having a high degree of cleanliness. In addition, it is effective to prevent the gas barrier layer surface from being scratched at the time of winding.

The protective sheet is not particularly limited, but it is possible to use a general “protective sheet” or “release sheet” having a configuration that an adhesive layer exhibiting weak adhesive property is imparted to a resin substrate having a film thickness of about 100 μm.

<<Water Vapor Transmission Rate of Gas Barrier Film>>

It is more preferable as the water vapor transmission rate of the gas barrier film of the present invention is lower, but for example, the water vapor transmission rate is preferably 0.001 to 0.00001 g/m²·24 hours and more preferably 0.0001 to 0.00001 g/m²·24 hours.

In the gas barrier film of the present invention, the method for measuring the water vapor transmission rate is not particularly limited, but in the present invention, the measurement was conducted using the following Ca method as the method for measuring the water vapor transmission rate.

<Ca Method Used in the Present Invention>

Deposition apparatus: vacuum deposition apparatus JEE-400 manufactured by JEOL Ltd.

Constant temperature and constant humidity oven: Yamato Humidic ChamberIG47M

Metal corroded by reaction with water: Calcium (granular)

Water vapor impermeable metal: aluminum (φ 3 to 5 mm, granular)

Fabrication of Cell for Water Vapor Barrier Property Evaluation

Metallic calcium was deposited on the gas barrier layer surface of the gas barrier film sample using a vacuum deposition apparatus (vacuum deposition apparatus JEE-400 manufactured by JEOL Ltd.). Incidentally, the rest of the gas barrier film sample other than the part (9 locations of 12 mm×12 mm) desired to be deposited was masked to conduct the deposition. Thereafter, the mask was removed therefrom as it was in the vacuum state, and aluminum was deposited on the entire surface of one side of the sheet from another metal deposition source. After aluminum sealing, the vacuum state was released, and immediately the aluminum sealed side of the gas barrier film sample was faced quartz glass having a thickness of 0.2 mm via an ultraviolet curable resin for sealing (manufactured by Nagase ChemteX Corporation) in a dry nitrogen gas atmosphere and irradiated with ultraviolet rays, whereby a cell for evaluation was fabricated. In addition, as presented in Examples to be described later, the same cells for water vapor barrier property evaluation were fabricated for the gas barrier film that was subjected to the bending treatment and the gas barrier film that was not subjected to the bending treatment in order to confirm a change in gas barrier property before and after bending.

The sample that was thus obtained and had both surfaces sealed was stored at a high temperature and a high humidity of 85° C. and 95% RH, and the amount of moisture that had transmitted into the cell was calculated from the quantity of corrosion of metallic calcium on the basis of the method described in JP-A No. 2005-283561.

Incidentally, in order to confirm that the water vapor does not transmit through the cell other than the gas barrier film surface, a sample fabricated by depositing metallic calcium on a quartz glass plate having a thickness of 0.2 mm was stored under the same condition of a high temperature and a high humidity of 85° C. and 95% RH as a comparative sample instead of the gas barrier film sample and it was confirmed that the corrosion of metallic calcium did not occur even after 100 hours elapsed.

[Electronic Device]

The gas barrier film of the present invention can be preferably used in a device of which the performance is deteriorated by the chemical components (oxygen, water, nitrogen oxides, sulfur oxides, ozone, and the like) in the air. In other words, the present invention provides an electronic device which includes an electronic device body and the gas barrier film of the present invention or a gas barrier film obtained by the producing method according to the present invention.

Examples of the device may include an electronic device such as an organic EL device, a liquid crystal display device (LCD), a thin film transistor, a touch panel, electronic paper, or a photovoltaic (PV) cell. The gas barrier film of the present invention is used preferably in an organic EL device or a photovoltaic cell and even more preferably in an organic EL device from the viewpoint of more efficiently obtaining the effect of the present invention.

The gas barrier film of the present invention can also be used to seal the film of a device. In other words, the surface of a device which serves as a support is provided with the gas barrier film of the present invention. The device may be covered with a protective layer before being provided with the gas barrier film.

The gas barrier film of the present invention can also be used as the substrate of a device or a film for sealing by a solid sealing method. The solid sealing method is a method in which a protective layer is formed on a device and an adhesive agent layer and a gas barrier film are then superimposed thereon and cured. The adhesive agent is not particularly limited, but examples thereof may include a thermosetting epoxy resin and a photocurable (meth)acrylate resin.

<Organic EL Device>

Examples of the organic EL device using a gas barrier film are described in detail in JP 2007-30387 A.

<Liquid Crystal Display Device>

A reflective liquid crystal display device has a configuration consisting of a lower substrate, a reflective electrode, a lower alignment film, a liquid crystal layer, an upper alignment film, a transparent electrode, an upper substrate, a λ/4 plate, and a polarizing film in order from the bottom. The gas barrier film of the present invention can be used as the substrate of the transparent electrode and the upper substrate. In the case of color display, it is preferable to further provide a color filter layer between the reflective electrode and the lower alignment film or between the upper alignment film and the transparent electrode. A transmission type liquid crystal display device has a configuration consisting of a backlight, a polarizing plate, a λ/4 plate, a lower transparent electrode, a lower alignment film, a liquid crystal layer, an upper alignment film, an upper transparent electrode, an upper substrate, a λ/4 plate, and a polarizing film in order from the bottom. In the case of color display, it is preferable to further provide a color filter layer between the lower transparent electrode and the lower alignment film or between the upper alignment film and the transparent electrode. The type of the liquid crystal cell is not particularly limited, and it is more preferably a TN (Twisted Nematic) type, a STN (Super Twisted Nematic) type, or a HAN (Hybrid Aligned Nematic) type, a VA (Vertically Alignment) type, an ECB (Electrically Controlled Birefringence) type, an OCB (Optically Compensated Bend) type, an IPS (In-Plane Switching) type, and a CPA (Continuous Pinwheel Alignment) type.

<Photovoltaic Cell>

The gas barrier film of the present invention can also be used as a sealing film of a photovoltaic cell device. Here, it is preferable to seal the photovoltaic cell device with the gas barrier film of the present invention so that the gas barrier layer becomes the side near to the photovoltaic cell device. The photovoltaic cell device in which the gas barrier film of the present invention is preferably used is not particularly limited, but examples thereof may include a single crystal silicon-based photovoltaic cell device, a polycrystalline silicon-based photovoltaic cell device, an amorphous silicon-based photovoltaic cell device of a single junction type or a tandem structure type, a semiconductor-based photovoltaic cell device of a III-V group compound such as gallium arsenide (GaAs) or indium phosphide (InP), a semiconductor-based photovoltaic cell device of a II-VI group compound such as cadmium telluride (CdTe), a semiconductor-based photovoltaic cell device of a I-III-VI group compound such as copper/indium/selenium-based (so-called CIS-based), copper/indium/gallium/selenium-based (so-called CIGS-based), copper/indium/gallium/selenium/sulfur-based (so called CIGSS-based), a dye-sensitized photovoltaic cell device, and an organic photovoltaic cell device. Among them, in the present invention, the photovoltaic cell device is preferably a semiconductor-based photovoltaic cell device of a I-III-VI group compound such as copper/indium/selenium-based (so-called CIS-based), copper/indium/gallium/selenium-based (so-called CIGS-based), copper/indium/gallium/selenium/sulfur-based (so called CIGSS-based).

<Others>

Examples of other applications may include a thin film transistor described in JP 10-512104 W, a touch panel described in JP 5-127822 A and JP 2002-48913 A, and electronic paper described in JP 2000-98326 A.

<Optical Member>

The gas barrier film of the present invention can also be used as an optical member. Examples of the optical member may include a circularly polarizing plate.

(Circularly Polarizing Plate)

It is possible to fabricate a circularly polarizing plate by stacking a λ/4 plate and a polarizing plate on the gas barrier film of the present invention serving as the substrate. In this case, stacking is conducted such that the angle formed by the slow axis of the λ/4 plate and the absorption axis of the polarizing plate becomes 45°. As such a polarizing plate, it is preferable to use those which are stretched in the direction of 45° with respect to the machine direction (MD), and for example, those described in JP 2002-865554 A can be suitably used.

### EXAMPLES

The effect of the present invention will be described with reference to the following Examples and Comparative Examples. However, the technical scope of the present invention is not limited only to the following Examples. In addition, the denotation “part” or “%” used in Examples represents “parts by mass” or “% by mass” unless otherwise specified.

The following three kinds were prepared as the substrate.

Substrate A: transparent resin substrate with hard coat layer (intermediate layer) (polyethylene terephthalate (PET) film with clear hard coat (CHC) layer manufactured by KIMOTO CO., LTD., the hard coat layer is composed of a UV curing resin containing an acrylic resin as a main component, the thickness of PET is 125 μm, and the thickness of CHC is 6 μm).

Those obtained by changing only the transparent resin substrate of the substrate A to the following ones were used as the substrates B and C.

Substrate B: Melinex (registered trademark) (manufactured by Teijin DuPont Films Japan Limited, model number: 542, thickness: 50 μm)

Substrate C: Teijin (registered trademark) Tetoron (registered trademark) film (manufactured by TEIJIN LIMITED., model number: G2P2, thickness: 25 μm).

### Comparative Example 1

### Formation of First to Fourth Gas Barrier Layers (Polysilazane Coating Layer)

<Preparation of Polysilazane-Containing Coating Liquid>

A dibutyl ether solution containing 20% by mass of perhydropolysilazane (PHPS) which did not contain a catalyst (NN120-20 manufactured by AZ Electronic Materials Co., Ltd) and a dibutyl ether solution containing 1% by mass of an amine catalyst (N,N,N′,N′-tetramethyl-1,6-diaminohexane) and 19% by mass of perhydropolysilazane (NAX120-20 manufactured by AZ Electronic Materials Co., Ltd) were mixed at a proportion of 4:1, and further the mixture was diluted and adjusted with the dibutyl ether solvent so that the solid content of the coating liquid became 5% by mass.

<Simultaneous Multilayer Coating>

A slide hopper coating apparatus capable of conducting four-layer simultaneous multilayer coating was used. The polysilazane-containing coating liquid prepared above was coated on the substrate A which had a size of 210 mm×350 mm and heated to 23° C. as the substrate by simultaneous multilayer coating of four layers in total such that the film thickness of each layer became 30 nm when dried while maintaining the temperature of the coating liquid at 23° C.

Immediately after coating, the coating film was set by blowing cold air at 15° C. At this time, the time (setting time) required until nothing was stuck to the finger when the surface was touched with a finger was 1 minute.

After setting was completed, the coating film was dried by blowing hot air at 80° C., thereby forming a coating layer constituted by four layers.

After forming the coating layer, the vacuum ultraviolet ray irradiation treatment of the coating layer was conducted from the side of the polysilazane coating layer that is the fourth gas barrier layer and is farthest from the substrate by the apparatus and method to be described below, thereby fabricating a gas barrier film (Sample No. 1).

Ultraviolet Ray Irradiating Apparatus

Excimer irradiating apparatus MODEL: MECL-M-1-200 manufactured by M. D. COM, inc.

Wavelength: 172 nm, stage temperature: 100° C.

Integrated quantity of light 3500 mJ/cm², concentration of oxygen: 0.1% by volume.

<Condition of Vacuum Ultraviolet Ray Irradiation and Measurement of Irradiation Energy>

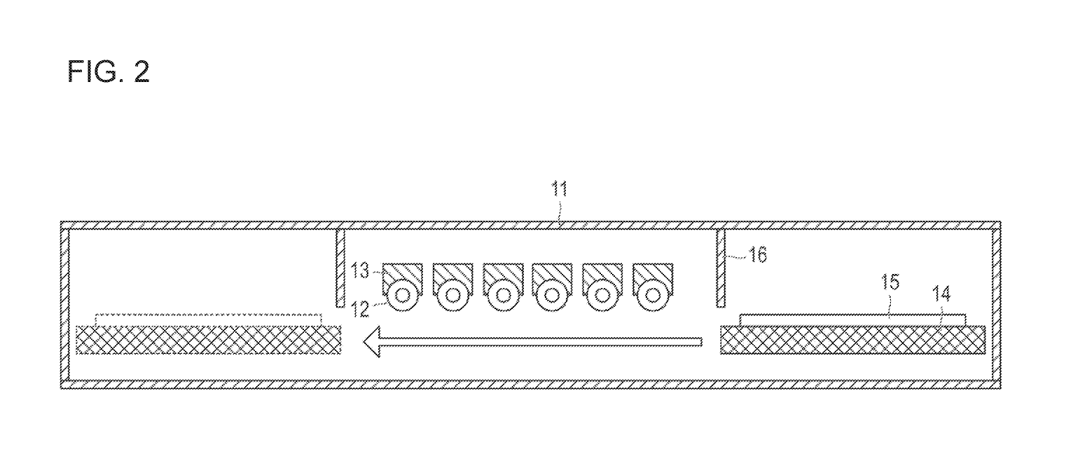

Vacuum ultraviolet ray irradiation was conducted using the apparatus illustrated as a schematic sectional diagram in FIG. 2.

In FIG. 2, 11 is an apparatus chamber, and it is possible to substantially remove the water vapor from the inside of the chamber and to maintain the concentration of oxygen at a predetermined concentration by supplying a suitable amount of nitrogen and oxygen to the inside thereof through the gas supply port that is not illustrated and exhausting them through the gas discharge port that is not illustrated. 12 is an Xe excimer lamp having a double tube structure to irradiate vacuum ultraviolet rays of 172 nm, 13 is a holder for the excimer lamp which also serves as an external electrode. 14 is a sample stage. The sample stage 14 can be horizontally reciprocated at a predetermined speed in the apparatus chamber 11 by a moving means that is not illustrated. In addition, the sample stage 14 can be maintained at a predetermined temperature by a heating means that is not illustrated. 15 is a sample on which the polysilazane coating layer is formed. The height of the sample stage is adjusted so that the shortest distance between the coating layer surface of the sample and the excimer lamp tube surface become 3 mm when the sample stage is horizontally moved. 16 is a light shielding plate, and it prevents the coating layer of the sample from being irradiated with vacuum ultraviolet light during aging of the Xe excimer lamp 12.

The energy irradiated on the coating film surface in the vacuum ultraviolet ray irradiating step was measured using an integrated light quantity meter for ultraviolet rays: C8026/H8025 UV POWER METER manufactured by Hamamatsu Photonics K.K. and a sensor head of 172 nm. Upon the measurement, the sensor head was installed in the center of the sample stage 14 so that the shortest distance between the Xe excimer lamp tube surface and the measurement surface of the sensor head became 3 mm, and nitrogen and oxygen was supplied into the apparatus chamber 11 so that the atmosphere therein had the same concentration of oxygen as in the vacuum ultraviolet ray irradiating step, and the sample stage 14 was moved at a speed of 0.5 m/min to conduct the measurement. Prior to the measurement, in order to stabilize the intensity of illumination of the Xe excimer lamp 12, 10 minutes of aging time was provided after turning on the Xe excimer lamp, and the sample stage was then moved to start the measurement.

The irradiation energy was adjusted to 3500 mJ/cm² by adjusting the moving speed of the sample stage on the basis of the irradiation energy obtained in this measurement. Incidentally, the vacuum ultraviolet ray irradiation was conducted after 10 minutes of aging in the same manner as in the irradiation energy measurement.

### Comparative Example 2

A gas barrier film (Sample No. 2) was fabricated in the same manner as in Comparative Example 1 except that a temperature treatment was further conducted at 40° C. for 24 hours after the vacuum ultraviolet ray irradiation.

### Comparative Example 3

A gas barrier film (Sample No. 3) was fabricated in the same manner as in Comparative Example 1 except that the substrate A was changed to the substrate B.

### Comparative Example 4

A gas barrier film (Sample No. 4) was fabricated in the same manner as in Comparative Example 3 except that a temperature treatment was further conducted at 40° C. for 24 hours after the vacuum ultraviolet ray irradiation.

### Comparative Example 5

A gas barrier film (Sample No. 5) was fabricated in the same manner as in Comparative Example 1 except that the substrate A was changed to the substrate C.

### Comparative Example 6

A gas barrier film (Sample No. 6) was fabricated in the same manner as in Comparative Example 3 except that a temperature treatment was further conducted at 40° C. for 24 hours after the vacuum ultraviolet ray irradiation.

### Comparative Example 7

The polysilazane-containing coating liquid prepared in Comparative Example 1 was coated on the substrate A using a spin coater so as to form a film having a thickness of 30 nm, and the resultant was left to stand for 2 minutes and then subjected to the additional heating treatment for 1 minute in a hot plate at 80° C., thereby forming a polysilazane coating layer. Thereafter, the polysilazane coating layer was subjected to the vacuum ultraviolet ray irradiation by the apparatus and method of Comparative Example 1, thereby forming the first gas barrier layer.

The second to fourth gas barrier layers were formed by repeating the same method as in the formation of this first gas barrier layer further three times, thereby fabricating a gas barrier film (Sample No. 7).

### Comparative Example 8

A gas barrier film (Sample No. 8) was fabricated in the same manner as in Comparative Example 7 except that a temperature treatment was further conducted at 40° C. for 24 hours after the formation of the fourth gas barrier layer.

### Comparative Example 9

A gas barrier film (Sample No. 9) was fabricated in the same manner as in Comparative Example 7 except that the substrate A was changed to the substrate B.

### Comparative Example 10

A gas barrier film (Sample No. 10) was fabricated in the same manner as in Comparative Example 9 except that a temperature treatment was further conducted at 40° C. for 24 hours after the formation of the fourth gas barrier layer.

### Comparative Example 11

A gas barrier film (Sample No. 11) was fabricated in the same manner as in Comparative Example 7 except that the substrate A was changed to the substrate C.

### Comparative Example 12

A gas barrier film (Sample No. 12) was fabricated in the same manner as in Comparative Example 11 except that a temperature treatment was further conducted at 40° C. for 24 hours after the formation of the fourth gas barrier layer.

### Example 1

The aluminum-containing coating liquid was prepared by the following method.

<Preparation of Aluminum-Containing Coating Liquid>

A mixture prepared by mixing 2.318 g of the mixture prepared by mixing a dibutyl ether solution containing 20% by mass of perhydropolysilazane (PHPS) which did not contain a catalyst (NN120-20 manufactured by AZ Electronic Materials Co., Ltd) and a dibutyl ether solution containing 1% by mass of an amine catalyst (N,N,N′,N′-tetramethyl-1,6-diaminohexane) and 19% by mass of perhydropolysilazane (NAX120-20 manufactured by AZ Electronic Materials Co., Ltd) at a proportion of 4:1, 0.306 g of ALCH (aluminum ethylacetoacetate diisopropylate manufactured by Kawaken Fine Chemicals Co., Ltd.), and 12.776 g of dibutyl ether was used as a coating liquid.

A gas barrier film (Sample No. 13) was fabricated in the same manner as in Comparative Example 1 except that the simultaneous multilayer coating was conducted such that a coating layer (farthest coating layer from the substrate) to be the fourth gas barrier layer was formed from the aluminum-containing coating liquid obtained above. The content of aluminum in the fourth gas barrier layer was 40% by mass.

### Example 2

A gas barrier film (Sample No. 14) was fabricated in the same manner as in Example 1 except that a temperature treatment was further conducted at 40° C. for 24 hours after the vacuum ultraviolet ray irradiation.

### Example 3

A gas barrier film (Sample No. 15) was fabricated in the same manner as in Example 1 except that the substrate A was changed to the substrate B.

### Example 4

A gas barrier film (Sample No. 16) was fabricated in the same manner as in Example 3 except that a temperature treatment was further conducted at 40° C. for 24 hours after the vacuum ultraviolet ray irradiation.

### Example 5

A gas barrier film (Sample No. 17) was fabricated in the same manner as in Example 1 except that the substrate A was changed to the substrate C.

### Example 6

A gas barrier film (Sample No. 18) was fabricated in the same manner as in Example 5 except that a temperature treatment was further conducted at 40° C. for 24 hours after the vacuum ultraviolet ray irradiation.

### Example 7

A gas barrier film (Sample No. 19) was fabricated in the same manner as in Comparative Example 1 except that the simultaneous multilayer coating was conducted such that an aluminum-containing polysilazane coating layer to be the second gas barrier layer and an aluminum-containing polysilazane coating layer to be the fourth gas barrier layer were formed using the aluminum-containing coating liquid prepared in Example 1. The content of aluminum in the second gas barrier layer and the fourth gas barrier layer was 40% by mass, respectively.

### Example 8

A gas barrier film (Sample No. 20) was fabricated in the same manner as in Example 7 except that a temperature treatment was further conducted at 40° C. for 24 hours after the vacuum ultraviolet ray irradiation.

### Example 9

A gas barrier film (Sample No. 21) was fabricated in the same manner as in Example 7 except that the substrate A was changed to the substrate B.

### Example 10

A gas barrier film (Sample No. 22) was fabricated in the same manner as in Example 9 except that a temperature treatment was further conducted at 40° C. for 24 hours after the vacuum ultraviolet ray irradiation.

### Example 11

A gas barrier film (Sample No. 23) was fabricated in the same manner as in Example 7 except that the substrate A was changed to the substrate C.

### Example 12

A gas barrier film (Sample No. 24) was fabricated in the same manner as in Example 11 except that a temperature treatment was further conducted at 40° C. for 24 hours after the vacuum ultraviolet ray irradiation.

### Example 13

A gallium-containing coating liquid was prepared by adding 0.306 g of gallium(III) isopropoxide (manufactured by Wako Pure Chemical Industries, Ltd.) instead of the ALCH in the aluminum-containing coating liquid prepared in Example 1 above. A gas barrier film (Sample No. 25) was fabricated in the same manner as in Example 9 except that the simultaneous multilayer coating was conducted such that a gallium-containing polysilazane coating layer to be the second gas barrier layer and a gallium-containing polysilazane coating layer to be the fourth gas barrier layer were formed using this gallium-containing coating liquid.

### Example 14

An indium-containing coating liquid was prepared by adding 0.306 g of indium(III) isopropoxide (manufactured by Wako Pure Chemical Industries, Ltd.) instead of the ALCH in the aluminum-containing coating liquid prepared in Example 1 above. A gas barrier film (Sample No. 26) was fabricated in the same manner as in Example 9 except that the simultaneous multilayer coating was conducted such that an indium-containing polysilazane coating layer to be the second gas barrier layer and an indium-containing polysilazane coating layer to be the fourth gas barrier layer were formed using this indium-containing coating liquid.

### Example 15

A magnesium-containing coating liquid was prepared by adding 0.306 g of magnesium ethoxide (manufactured by Wako Pure Chemical Industries, Ltd.) instead of the ALCH in the aluminum-containing coating liquid prepared in Example 1 above. A gas barrier film (Sample No. 27) was fabricated in the same manner as in Example 9 except that the simultaneous multilayer coating was conducted such that a magnesium-containing polysilazane coating layer to be the second gas barrier layer and a magnesium-containing polysilazane coating layer to be the fourth gas barrier layer were formed using this magnesium-containing coating liquid.

### Example 16

A calcium-containing coating liquid was prepared by adding 0.306 g of calcium isopropoxide (manufactured by Wako Pure Chemical Industries, Ltd.) instead of the ALCH in the aluminum-containing coating liquid prepared in Example 1 above. A gas barrier film (Sample No. 28) was fabricated in the same manner as in Example 9 except that the simultaneous multilayer coating was conducted such that a calcium-containing polysilazane coating layer to be the second gas barrier layer and a calcium-containing polysilazane coating layer to be the fourth gas barrier layer were formed using this calcium-containing coating liquid.

### Example 17

A boron-containing coating liquid was prepared by adding 0.306 g of triisopropyl borate (manufactured by Wako Pure Chemical Industries, Ltd.) instead of the ALCH in the aluminum-containing coating liquid prepared in Example 1 above. A gas barrier film (Sample No. 29) was fabricated in the same manner as in Example 9 except that the simultaneous multilayer coating was conducted such that a boron-containing polysilazane coating layer to be the second gas barrier layer and a boron-containing polysilazane coating layer to be the fourth gas barrier layer were formed using this boron-containing coating liquid.

### Comparative Example 13

A rhodium-containing coating liquid was prepared by adding 0.306 g of tris(dibutylsulfide)rhodium chloride [tris(dibutylsulfide)RhCl₃ manufactured by Gelest, Inc.] instead of the ALCH in the aluminum-containing coating liquid prepared in Example above. A gas barrier film (Sample No. 30) was fabricated in the same manner as in Example 9 except that the simultaneous multilayer coating was conducted such that a rhodium-containing polysilazane coating layer to be the second gas barrier layer and a rhodium-containing polysilazane coating layer to be the fourth gas barrier layer were formed using this rhodium-containing coating liquid.

### Comparative Example 14

### Formation of First Gas Barrier Layer (Deposition Method)

The first gas barrier layer was formed by an atmospheric pressure plasma method (deposited gas barrier layer) using an atmospheric pressure plasma film forming apparatus of a roll-to-roll form as illustrated in FIG. 1. Specifically, the first gas barrier layer (thickness: 30 nm) composed of silicon oxycarbide (SiOC) was formed on the substrate B having a size of 210 mm×350 mm under the condition for thin film formation presented in the following Table 1. The elastic modulus E1 of the first gas barrier layer was measured by a nanoindentation method, and the result was 30 GPa to be consistent in the film thickness direction.

TABLE 1

(Mixed gas composition)
Discharge gas: nitrogen gas 94.9% by volume
Thin film forming gas: tetraethoxysilane 0.1% by volume
Additive gas: oxygen gas 5.0% by volume
(Film deposition condition)
<First electrode side>
Kind of power supply: 100 kHz (continuous mode) PHF-6k
manufactured by HAIDEN LABORATORY
Frequency: 100 kHz
Power density: 10 W/cm²
Electrode temperature: 120° C.
<Second electrode side>
Kind of power supply: 13.56 MHz CF-5000-13M manufactured
by PEARL KOGYO Co., Ltd.
Frequency: 13.56 MHz
Power density: 10 W/cm²
Electrode temperature: 90° C.

[Formation of Second and Third Gas Barrier Layers (Polysilazane Coating Layer)]

The polysilazane-containing coating liquid prepared in Comparative Example 1 was coated on the first gas barrier layer using a spin coater so as to form a film having a thickness of 30 nm, and the resultant was left to stand for 2 minutes and then subjected to the additional heating treatment for 1 minute in a hotplate at 80° C., thereby forming the second polysilazane coating layer. Thereafter, the polysilazane coating layer was subjected to the vacuum ultraviolet ray irradiation (however, integrated quantity of light was 2000 mJ/cm²) by the apparatus and method described above, thereby forming the second gas barrier layer.

The third gas barrier layer was further formed on this second gas barrier layer by the same method as in the formation of the second gas barrier layer. In this manner, a gas barrier film (Sample No. 31) was fabricated.

### Comparative Example 15

A gas barrier film (Sample No. 32) was fabricated by the same method as in Comparative example 14 except that the coating layer to be the second gas barrier layer and the coating layer to be the third gas barrier layer were formed by simultaneous multilayer coating, dried, and subjected to the vacuum ultraviolet ray irradiation (integrated quantity of light was 2000 mJ/cm²) so as to be irradiated from the side of the coating layer to be the third gas barrier layer.

### Example 18

A gas barrier film (Sample No. 33) was fabricated in the same manner as in Comparative Example 15 except that the simultaneous multilayer coating was conducted such that an aluminum-containing polysilazane coating layer to be the third gas barrier layer was formed using the aluminum-containing coating liquid prepared in Example 1.

### Example 19

A gas barrier film (Sample No. 34) was fabricated in the same manner as in Comparative Example 15 except that the simultaneous multilayer coating was conducted such that an aluminum-containing polysilazane coating layer to be the second gas barrier layer was formed using the aluminum-containing coating liquid prepared in Example 1.

<<Evaluation of Planarity>>

For the planarity-related curling after cutting the sample thus obtained into an A4 size, the handling was evaluated by 20 persons. The evaluation was carried out by each person in five ranks as to be presented below. The total score by 20 persons was evaluated up to 100 to 20 points, and the sample which has a greater total score exhibits more favorable handleability.

5: there are no handling problems at all

4: there are a few curls but there are no handling problems

3: there are some curls and handling problems are concerned

2: there are curls and there are handling problems

1: there are curls, handling such as post-processing is impossible, and thus N.G.

<<Evaluation of Water Vapor Barrier Property>>

For the gas barrier films fabricated in the above, a sample (immediately) before being exposed to a high temperature and a high humidity of 85° C. and 95% RH for 100 hours and a sample (after DH 100 hours) which was exposed to a high temperature and a high humidity of 85° C. and 95% RH for 100 hours were prepared, respectively.

The evaluation on water vapor barrier property was carried out by forming an 80 nm thick film of metallic calcium on the gas barrier film by deposition and evaluating the time required for calcium formed into a film to be 50% of the area as the 50% area time (see below). The 50% area times before and after being exposed for 100 hours were evaluated, and the retention rate (%) was calculated by 50% area time after being exposed/50% area time before being exposed and presented in Table 3. As the indicator of the retention rate, it was judged to be acceptable when the retention rate was 70% or more and it was judged to be unacceptable when the retention rate was less than 70%.

(Metallic Calcium Film Forming Apparatus)

Deposition apparatus: vacuum vapor deposition apparatus JEE-400 manufactured by JEOL Ltd.

Constant temperature and constant humidity oven: Yamato Humidic ChamberIG47M

(Raw Materials)

Metal corroded by reaction with water: Calcium (granular)

Water vapor impermeable metal: aluminum (φ 3 to 5 mm, granular)

(Fabrication of Sample for Water Vapor Barrier Property Evaluation)

Metallic calcium was deposited on the gas barrier layer surface of the outermost layer of the gas barrier film thus fabricated through the mask in a size of 12 mm×12 mm using a vacuum deposition apparatus (vacuum deposition apparatus JEE-400 manufactured by JEOL Ltd.). At this time, the thickness of the deposited film was set to 80 nm.

Thereafter, the mask was removed therefrom as it was in the vacuum state, and aluminum was deposited on the entire surface of one side of the sheet to temporarily seal. Subsequently, the vacuum state was released, and the resultant was immediately moved into a dry nitrogen gas atmosphere, quartz glass having a thickness of 0.2 mm was pasted to the aluminum deposited surface via an ultraviolet curable resin for sealing (manufactured by Nagase ChemteX Corporation), the resin was cured and stuck by irradiating with ultraviolet rays to mainly seal the resultant, thereby fabricating the sample for water vapor barrier property evaluation.

The sample thus obtained was stored at a high temperature and a high humidity of 85° C. and 95% RH, and it was observed that the corrosion of metallic calcium had proceeded with the storage time. Upon observation, the time required for that the area in which metallic calcium had corroded became 50% with respect to the metallic calcium deposited area of 12 mm×12 mm was determined by interpolating the observed result in a straight line.

<<Evaluation on Adhesive Force>>

The cross-cut test using 100 squares was carried out in conformity with JIS K 5400: 1990. The adhesive force is stronger as the number of squares that were not peeled off was more among the 100 squares.

This test was carried out for both of the sample (immediately) before being exposed to a high temperature and a high humidity of 85° C. and 95% RH for 100 hours and the sample (after DH 100 hours) after being exposed to a high temperature and a high humidity of 85° C. and 95% RH for 100 hours.

<<Evaluation on Folding Resistance>>

Each of the gas barrier films was repeatedly bent at an angle of 180° so as to have a radius of curvature of 2 mm 150 times. Thereafter, the water vapor transmission rate (water vapor barrier property) thereof was then measured in the same manner as above, the degree of deterioration resistance was calculated by the following Equation from a change in water vapor transmission rate before and after bending, and the folding resistance was evaluated according to the following criteria.

Degree of deterioration resistance=(water vapor transmission rate after bending test/water vapor transmission rate before bending test)×100(%)

5: degree of deterioration resistance is 95% or more

4: degree of deterioration resistance is 85% or more and less than 95%

3: degree of deterioration resistance is 50% or more and less than 85%

2: degree of deterioration resistance is 10% or more and less than 50% and

1: degree of deterioration resistance is less than 10%.

This test was carried out for both of the sample (immediately) before being exposed to a high temperature and a high humidity of 85° C. and 95% RH for 100 hours and the sample (after DH 100 hours) after being exposed to a high temperature and a high humidity of 85° C. and 95% RH for 100 hours.

<<Evaluation on Cracking>>

The gas barrier film which was fabricated in the above and had a size of 100 mm×100 mm was stored at a high temperature and a high humidity of 85° C. and 95% RH for 100 hours. After storage, the number of cracks on the film surface was visually evaluated using the NQS-50 of studio spotlight NQS series manufactured by Panasonic Corporation and ranked as follows. The sample which has a smaller number of cracks is more favorable.

5: 0 piece

4: 1 to 4 pieces

3: 5 to 9 pieces

2: 10 to 19 pieces and

1: 20 or more pieces.

<<Fabrication of Organic Thin Film Electronic Device>>

An organic EL device of an organic thin film electronic device was fabricated using the gas barrier film fabricated in the above.

[Fabrication of Organic EL Device]

(Formation of First Electrode Layer)

ITO (indium tin oxide) was deposited on the gas barrier layer of the outermost layer of each of the gas barrier films in a thickness of 150 nm by the sputtering method, and the patterning thereof was conducted by photolithography, thereby forming the first electrode layer. Incidentally, the patterning was conducted so as to have a light emitting area of 50 mm².

(Formation of Hole Transport Layer)

The hole transport layer was formed by coating the coating liquid for hole transport layer formation to be described later on the first electrode layer of the gas barrier film on which the first electrode layer was formed using an extrusion coating machine and then drying it. The coating liquid for hole transport layer formation was coated so as to have a thickness after drying of 50 nm.

Before coating the coating liquid for hole transport layer formation, the cleaning surface modification treatment of the gas barrier film was conducted at an irradiation intensity of 15 mW/cm² and a distance 10 mm using a low pressure mercury lamp having a wavelength of 184.9 nm. A static eliminator by weak X-ray was used for the charge removal treatment.

<Coating Condition>

The coating step was conducted in the air and in an environment of 25° C. and a relative humidity of 50% RH.

<Preparation of Coating Liquid for Hole Transport Layer Formation>

A solution obtained by diluting polyethylene dioxythiophene polystyrene sulfonate (PEDOT/PSS, Baytron P AI 4083 manufactured by Bayer AG) with 65% of pure water and 5% of methanol was prepared as the coating liquid for hole transport layer formation.

<Drying and Heating Treatment Condition>

After coating the coating liquid for hole transport layer formation, the solvent was removed by blowing wind at a temperature of 100° C., a height toward the film formed surface of 100 mm, an ejection velocity of 1 m/s, and a wind speed distribution in width of 5%, and subsequently, a heat treatment by the backside heat transfer method was conducted at a temperature 150° C. using a heating treatment apparatus, thereby forming the hole transport layer.

(Formation of Light Emitting Layer)

Subsequently, the light emitting layer was formed by coating the coating liquid for white light emitting layer formation to be described below on the hole transport layer of the gas barrier film on which the hole transport layer was formed using the extrusion coating machine and then drying it. The coating liquid for white light emitting layer formation was coated so as to have a thickness of 40 nm after drying.

<Coating Liquid for White Light Emitting Layer Formation>

In 100 g of toluene, 1.0 g of the following H-A of a host material, 100 mg of the following D-A of a dopant material, 0.2 mg of the following D-B of a dopant material, and 0.2 mg of the following D-C of a dopant material were dissolved to prepared as the coating liquid for white light emitting layer formation.

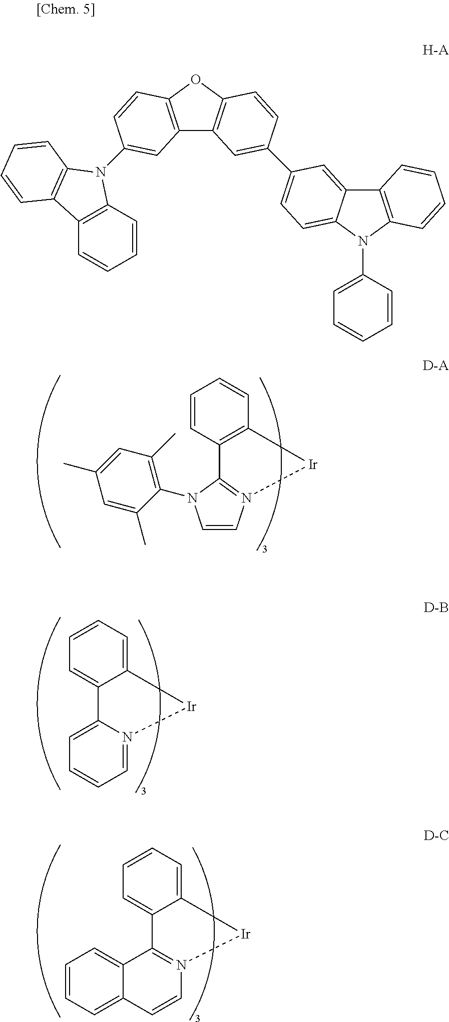

<Coating Condition>

The coating step was conducted in an atmosphere of the concentration of nitrogen gas of 99% by volume or more at a coating temperature of 25° C. and a coating speed of 1 m/min.

<Drying and Heating Treatment Condition>

After coating the coating liquid for white light emitting layer formation, the solvent was removed by blowing wind at a temperature of 60° C., a height toward the film formed surface of 100 mm, an ejection velocity of 1 m/s, and a wind speed distribution in width of 5%. Subsequently, a heating treatment was conducted at a temperature 130° C., thereby forming the light emitting layer.

(Formation of Electron Transport Layer)

Next, the electron transport layer was formed by coating the coating liquid for electron transport layer formation to be described below using the extrusion coating machine and then drying it. The coating liquid for electron transport layer formation was coated so as to have a thickness after drying of 30 nm.

<Coating Condition>

The coating step was conducted in an atmosphere of the concentration of nitrogen gas of 99% by volume or more at a coating temperature of the coating liquid for electron transport layer formation of 25° C. and a coating speed of 1 m/min.

<Coating Liquid for Electron Transport Layer Formation>

For the electron transport layer, a solution of 0.5% by mass of the following E-A was prepared by dissolving the E-A in 2,2,3,3-tetrafluoro-1-propanol to use as the coating liquid for electron transport layer formation.

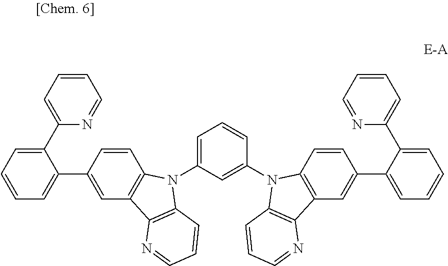 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

<Drying and Heating Treatment Condition>

After coating the coating liquid for electron transport layer formation, the solvent was removed by blowing wind at a temperature of 60° C., a height toward the film formed surface of 100 mm, an ejection velocity of 1 m/s, and a wind speed distribution in width of 5%. Subsequently, a heating treatment was conducted at a temperature 200° C. in the heating treatment unit, thereby forming the electron transport layer.

(Formation of Electron Injection Layer)

Next, the electron injection layer was formed on the electron transport layer thus formed. First, the substrate was introduced into a reduced pressure chamber, the pressure was reduced to 5×10⁻⁴ Pa. Cesium fluoride which had been previously prepared in the tantalum deposition boat of the vacuum chamber was heated to form an electron injection layer having a thickness of 3 nm.

(Formation of Second Electrode)

A mask pattern film formation was conducted on the electron injection layer thus formed excluding the part that became an extraction electrode on the first electrode using aluminum as the second electrode forming material in a vacuum of 5×10⁻⁴ Pa by a deposition method so as to have an extraction electrode and a light emitting area of 50 mm², thereby stacking the second electrode having a thickness of 100 nm.

(Cutting)

The gas barrier film on which the second electrode was formed was again moved into a nitrogen atmosphere and cut into a prescribed size using an ultraviolet laser.

(Connection of Electrode Lead)

A flexible printed circuit board (Base Film: polyimide of 12.5 μm, rolled copper foil: 18 μm, coverlay: polyimide of 12.5 μm, surface treatment: NiAu plating) was connected to the organic EL device thus fabricated using the anisotropic conductive film DP3232S9 manufactured by Dexerials Corporation.

Crimping Condition: crimping was conducted for 10 seconds at a temperature of 170° C. (ACF temperature measured separately using a thermocouple: 140° C.) and a pressure of 2 MPa.

(Sealing)

The sealing member was stuck to the organic EL device connected to the electrode lead (flexible printed circuit board) using a commercially available roll laminator, thereby fabricating an organic EL device.

Incidentally, one (thickness of adhesive agent layer: 1.5 μm) obtained by laminating a polyethylene terephthalate (PET) film (12 μm thick) on a 30 μm thick aluminum foil (manufactured by Toyo Aluminum K.K.) using an adhesive agent for dry lamination (urethane-based adhesive agent of two-liquid reaction type) was used as the sealing member.

A thermosetting adhesive agent was uniformly coated on the aluminum surface along the stuck surface (glossy surface) of the aluminum foil in a thickness of 20 μm using a dispenser.

As the thermosetting adhesive agent, the following epoxy adhesive agent was used.

Bisphenol A diglycidyl ether (DGEBA)

Dicyandiamide (DICY)

Epoxy adduct curing promotor.

Thereafter, a sealing substrate was closely disposed so as to cover the junction portion between the extraction electrode and the electrode lead and closely sealed using a crimping roll under a crimping condition: crimping roll temperature of 120° C., pressure of 0.5 MPa, device speed of 0.3 m/min.

<<Evaluation of Organic EL Device>>

The evaluation on the durability of the organic EL device thus fabricated was carried out in accordance with the following method.

[Evaluation on Durability]

(Accelerated Deterioration Treatment)

Each of the organic EL devices thus fabricated was subjected to the accelerated deterioration treatment in an environment of 85° C. and 95% RH for 100 hours and then to the following evaluation on black spot together with the organic EL device that was not subjected to the accelerated deterioration treatment.

(Evaluation on Black Spot)

The organic EL device that was subjected to the accelerated deterioration treatment and the organic EL device that was not subjected to the accelerated deterioration treatment were allowed to continuously emit light for 24 hours by applying a current of 1 mA/cm² to each of them, a part of the panel was then magnified using a 100-fold microscope (MS-804 and lens MP-ZE25-200 manufactured MORITEX Corporation) and photographed. The photographic image was cut into 2 mm², the ratio of the area having a black spot was determined, the device deterioration resistance rate was calculated by the following Equation, and the durability was evaluated according to the following criteria. It was judged to have practically preferable properties when the evaluation rank was ⊚.

Device deterioration resistance rate=(area of black spot generated in device that was not subjected to accelerated deterioration treatment/area of black spot generated in device that was subjected to accelerated deterioration treatment)×100(%)

⊚: device deterioration resistance rate is 90% or more

◯: device deterioration resistance rate is 60% or more and less than 90%

Δ: device deterioration resistance rate is 20% or more and less than 60% and

X: device deterioration resistance rate is less than 20%

This evaluation was carried out for both of the sample (immediately) before being exposed to a high temperature and a high humidity of 85° C. and 95% RH for 100 hours and the sample (after DH 100 hours) after being exposed to a high temperature and a high humidity of 85° C. and 95% RH for 100 hours.

The configuration of the gas barrier film of the respective Examples and the respective Comparative Examples and the evaluation results are presented in the following Table 2 and the following Table 3, respectively. Incidentally, in the columns for the “modification treatment” and the “temperature treatment” in Table 2, whether the corresponding treatment was conducted immediately after the fabrication of the corresponding layer (coating layer) or not was indicated.

TABLE 2

| | | | Thickness | First gas barrier layer | | Second gas barrier layer | | Third gas barrier layer | | Fourth gas barrier layer | | |
|---|---|---|---|---|---|---|---|---|---|---|---|---|
| | | | of | | Modification | | Modification | | Modification | | Modification | |
| | Sample | Coating | substrate | | treatment | | treatment | | treatment | | treatment | Temperature |
| | No. | method | (μm) | Configuration | (mJ/cm²) | Configuration | (mJ/cm²) | Configuration | (mJ/cm²) | Configuration | (mJ/cm²) | treatment |
| Comparative Example 1 | 1 | Simultaneous | 125 | PHPS 30 nm | Not | PHPS 30 nm | Not | PHPS 30 nm | Not | PHPS 30 nm | 3500 | Not |
| | | multilayer | | | conducted | | conducted | | conducted | | | conducted |
| Comparative Example 2 | 2 | ↑ | ↑ | ↑ | ↑ | ↑ | ↑ | ↑ | ↑ | ↑ | ↑ | 40° C. 24 hr |
| Comparative Example 3 | 3 | ↑ | 50 | ↑ | ↑ | ↑ | ↑ | ↑ | ↑ | ↑ | ↑ | Not |
| | | | | | | | | | | | | conducted |
| Comparative Example 4 | 4 | ↑ | ↑ | ↑ | ↑ | ↑ | ↑ | ↑ | ↑ | ↑ | ↑ | 40° C. 24 hr |
| Comparative Example 5 | 5 | ↑ | 25 | ↑ | ↑ | ↑ | ↑ | ↑ | ↑ | ↑ | ↑ | Not |
| | | | | | | | | | | | | conducted |
| Comparative Example 6 | 6 | ↑ | ↑ | ↑ | ↑ | ↑ | ↑ | ↑ | ↑ | ↑ | ↑ | 40° C. 24 hr |
| Comparative Example 7 | 7 | Sequential | 125 | ↑ | 3500 | ↑ | 3500 | ↑ | 3500 | ↑ | 3500 | Not |
| | | | | | | | | | | | | conducted |
| Comparative Example 8 | 8 | ↑ | ↑ | ↑ | ↑ | ↑ | ↑ | ↑ | ↑ | ↑ | ↑ | 40° C. 24 hr |
| Comparative Example 9 | 9 | ↑ | 50 | ↑ | ↑ | ↑ | ↑ | ↑ | ↑ | ↑ | ↑ | Not |
| | | | | | | | | | | | | conducted |
| Comparative Example 10 | 10 | ↑ | ↑ | ↑ | ↑ | ↑ | ↑ | ↑ | ↑ | ↑ | ↑ | 40° C. 24 hr |
| Comparative Example 11 | 11 | ↑ | 25 | ↑ | ↑ | ↑ | ↑ | ↑ | ↑ | ↑ | ↑ | Not |
| | | | | | | | | | | | | conducted |
| Comparative Example 12 | 12 | ↑ | ↑ | ↑ | ↑ | ↑ | ↑ | ↑ | ↑ | ↑ | ↑ | 40° C. 24 hr |
| Example 1 | 13 | Simultaneous | 125 | ↑ | Not | ↑ | Not | ↑ | Not | PHPS + Al | 3500 | Not |
| | | multilayer | | | conducted | | conducted | | conducted | 30 nm | | conducted |
| Example 2 | 14 | ↑ | ↑ | ↑ | ↑ | ↑ | ↑ | ↑ | ↑ | ↑ | ↑ | 40° C. 24 hr |
| Example 3 | 15 | ↑ | 50 | ↑ | ↑ | ↑ | ↑ | ↑ | ↑ | ↑ | ↑ | Not |
| | | | | | | | | | | | | conducted |
| Example 4 | 16 | ↑ | ↑ | ↑ | ↑ | ↑ | ↑ | ↑ | ↑ | ↑ | ↑ | 40° C. 24 hr |
| Example 5 | 17 | ↑ | 25 | ↑ | ↑ | ↑ | ↑ | ↑ | ↑ | ↑ | ↑ | Not |
| | | | | | | | | | | | | conducted |
| Example 6 | 18 | ↑ | ↑ | ↑ | ↑ | ↑ | ↑ | ↑ | ↑ | ↑ | ↑ | 40° C. 24 hr |
| Example 7 | 19 | Simultaneous | 125 | PHPS 30 nm | Not | PHPS + Al | Not | PHPS 30 nm | Not | PHPS + Al | 3500 | Not |
| | | multilayer | | | conducted | 30 nm | conducted | | conducted | 30 nm | | conducted |
| Example 8 | 20 | ↑ | ↑ | ↑ | ↑ | ↑ | ↑ | ↑ | ↑ | ↑ | ↑ | 40° C. 24 hr |
| Example 9 | 21 | ↑ | 50 | ↑ | ↑ | ↑ | ↑ | ↑ | ↑ | ↑ | ↑ | Not |
| | | | | | | | | | | | | conducted |
| Example 10 | 22 | ↑ | ↑ | ↑ | ↑ | ↑ | ↑ | ↑ | ↑ | ↑ | ↑ | 40° C. 24 hr |
| Example 11 | 23 | ↑ | 25 | ↑ | ↑ | ↑ | ↑ | ↑ | ↑ | ↑ | ↑ | Not |
| | | | | | | | | | | | | conducted |
| Example 12 | 24 | ↑ | ↑ | ↑ | ↑ | ↑ | ↑ | ↑ | ↑ | ↑ | ↑ | 40° C. 24 hr |
| Example 13 | 25 | ↑ | 50 | ↑ | ↑ | PHPS + Ga | ↑ | ↑ | ↑ | PHPS + Ga | ↑ | Not |
| | | | | | | 30 nm | | | | 30 nm | | conducted |
| Example 14 | 26 | ↑ | ↑ | ↑ | ↑ | PHPS + In | ↑ | ↑ | ↑ | PHPS + In | ↑ | ↑ |
| | | | | | | 30 nm | | | | 30 nm | | |
| Example 15 | 27 | ↑ | ↑ | ↑ | ↑ | PHPS + Mg | ↑ | ↑ | ↑ | PHPS + Mg | ↑ | ↑ |
| | | | | | | 30 nm | | | | 30 nm | | |
| Example 16 | 28 | ↑ | ↑ | ↑ | ↑ | PHPS + Ca | ↑ | ↑ | ↑ | PHPS + Ca | ↑ | ↑ |
| | | | | | | 30 nm | | | | 30 nm | | |
| Example 17 | 29 | ↑ | ↑ | ↑ | ↑ | PHPS + B | ↑ | ↑ | ↑ | PHPS + B | ↑ | ↑ |
| | | | | | | 30 nm | | | | 30 nm | | |
| Comparative Example 13 | 30 | ↑ | ↑ | ↑ | ↑ | PHPS + Rh | ↑ | ↑ | ↑ | PHPS + Rh | ↑ | ↑ |
| | | | | | | 30 nm | | | | 30 nm | | |
| Comparative Example 14 | 31 | Sequential | ↑ | SiOC 30 nm | ↑ | PHPS 30 nm | 2000 | ↑ | 2000 | — | — | — |
| Comparative Example 15 | 32 | Simultaneous | ↑ | ↑ | ↑ | ↑ | Not | ↑ | ↑ | — | — | — |
| | | multilayer | | | | | conducted | | | | | |
| Example 18 | 33 | ↑ | ↑ | ↑ | ↑ | ↑ | ↑ | PHPS + Al | ↑ | — | — | — |
| | | | | | | | | 30 nm | | | | |
| Example 19 | 34 | ↑ | ↑ | ↑ | ↑ | PHPS + Al | ↑ | PHPS 30 nm | ↑ | — | — | — |
| | | | | | | 30 nm | | | | | | |

TABLE 3

| | | | | | | | | | | Evaluation | | |
|---|---|---|---|---|---|---|---|---|---|---|---|---|
| | | | | | Folding resistance | | | | | on | Evaluation on | |
| | | | Adhesive property | | | After | Barrier property test | | | cracking | black spot | |
| | | | | After | | DH | | After DH | Reten- | After | | After |
| | Sample | | Imme- | DH 100 | Imme- | 100 | Imme- | 100 | tion | DH 100 | Imme- | DH 100 |
| | No. | Planarity | diately | hours | diately | hours | diately | hours | rate (%) | hours | diately | hours |
| Comparative | 1 | 83 | 8 | 1 | 1 | 1 | 48 | 5 | 10.4 | 1 | x | x |
| Example 1 | | | | | | | | | | | | |
| Comparative | 2 | 72 | 12 | 1 | 2 | 1 | 55 | 5 | 9.1 | 1 | x | x |
| Example 2 | | | | | | | | | | | | |
| Comparative | 3 | 63 | 8 | 1 | 1 | 1 | 51 | 8 | 15.7 | 1 | x | x |
| Example 3 | | | | | | | | | | | | |
| Comparative | 4 | 50 | 18 | 1 | 2 | 1 | 62 | 11 | 17.7 | 1 | x | x |
| Example 4 | | | | | | | | | | | | |
| Comparative | 5 | 51 | 10 | 1 | 1 | 1 | 50 | 9 | 18.0 | 1 | x | x |
| Example 5 | | | | | | | | | | | | |
| Comparative | 6 | 43 | 17 | 1 | 3 | 1 | 61 | 8 | 13.1 | 1 | x | x |
| Example 6 | | | | | | | | | | | | |
| Comparative | 7 | 32 | 35 | 20 | 4 | 2 | 111 | 21 | 18.9 | 3 | ○ | Δ |
| Example 7 | | | | | | | | | | | | |
| Comparative | 8 | 29 | 43 | 33 | 4 | 3 | 123 | 33 | 26.8 | 4 | ○ | Δ |
| Example 8 | | | | | | | | | | | | |
| Comparative | 9 | 25 | 35 | 12 | 3 | 1 | 61 | 32 | 52.5 | 1 | x | x |
| Example 9 | | | | | | | | | | | | |
| Comparative | 10 | 23 | 30 | 18 | 3 | 1 | 67 | 55 | 82.1 | 2 | x | x |
| Example 10 | | | | | | | | | | | | |
| Comparative | 11 | 20 | 7 | 2 | 2 | 1 | 40 | 30 | 75.0 | 1 | x | x |
| Example 11 | | | | | | | | | | | | |
| Comparative | 12 | 20 | 7 | 2 | 2 | 1 | 45 | 32 | 71.1 | 1 | x | x |
| Example 12 | | | | | | | | | | | | |
| Example 1 | 13 | 85 | 83 | 83 | 4 | 4 | 356 | 341 | 95.8 | 4 | ⊙ | ○ |
| Example 2 | 14 | 86 | 91 | 90 | 4 | 4 | 379 | 388 | 102.4 | 5 | ⊙ | ○ |
| Example 3 | 15 | 87 | 81 | 83 | 4 | 4 | 361 | 359 | 99.4 | 4 | ⊙ | ○ |
| Example 4 | 16 | 88 | 85 | 83 | 4 | 4 | 388 | 387 | 99.7 | 5 | ⊙ | ○ |
| Example 5 | 17 | 85 | 83 | 83 | 4 | 4 | 373 | 370 | 99.2 | 4 | ⊙ | ○ |
| Example 6 | 18 | 84 | 84 | 83 | 5 | 4 | 380 | 377 | 99.2 | 5 | ⊙ | ○ |
| Example 7 | 19 | 100 | 95 | 92 | 5 | 4 | 521 | 501 | 96.2 | 5 | ⊙ | ⊙ |
| Example 8 | 20 | 100 | 100 | 98 | 5 | 5 | 536 | 512 | 95.5 | 5 | ⊙ | ⊙ |
| Example 9 | 21 | 100 | 96 | 93 | 5 | 4 | 523 | 520 | 99.4 | 5 | ⊙ | ⊙ |
| Example 10 | 22 | 100 | 100 | 98 | 5 | 5 | 538 | 537 | 99.8 | 5 | ⊙ | ⊙ |
| Example 11 | 23 | 100 | 92 | 92 | 5 | 4 | 508 | 505 | 99.4 | 5 | ⊙ | ⊙ |
| Example 12 | 24 | 99 | 99 | 99 | 5 | 5 | 511 | 507 | 99.2 | 5 | ⊙ | ⊙ |
| Example 13 | 25 | 99 | 92 | 90 | 5 | 4 | 501 | 498 | 99.4 | 5 | ⊙ | ⊙ |
| Example 14 | 26 | 98 | 91 | 91 | 5 | 4 | 508 | 490 | 96.5 | 5 | ⊙ | ⊙ |
| Example 15 | 27 | 100 | 90 | 91 | 5 | 4 | 511 | 499 | 97.7 | 5 | ⊙ | ⊙ |
| Example 16 | 28 | 100 | 92 | 92 | 4 | 4 | 510 | 503 | 98.6 | 5 | ⊙ | ⊙ |
| Example 17 | 29 | 99 | 93 | 93 | 5 | 4 | 509 | 504 | 99.0 | 5 | ⊙ | ⊙ |
| Comparative | 30 | 83 | 35 | 5 | 3 | 2 | 40 | 5 | 12.5 | 2 | Δ | x |
| Example 13 | | | | | | | | | | | | |
| Comparative | 31 | 30 | 70 | 21 | 3 | 1 | 211 | 51 | 24.1 | 1 | ○ | x |
| Example 14 | | | | | | | | | | | | |
| Comparative | 32 | 47 | 35 | 1 | 1 | 1 | 51 | 12 | 23.5 | 1 | Δ | x |
| Example 15 | | | | | | | | | | | | |
| Example 18 | 33 | 89 | 88 | 79 | 5 | 5 | 478 | 466 | 97.4 | 5 | ⊙ | ⊙ |
| Example 19 | 34 | 78 | 78 | 72 | 4 | 4 | 410 | 388 | 94.6 | 5 | ⊙ | ○ |

As can be seen from Table 3, the gas barrier films of the present invention which are fabricated in Examples exhibit high gas barrier property even though a thinner substrate is used as compared to the prior art, and the gas barrier films of the present invention exhibit excellent interlayer adhesive force and bending resistance and suppressed occurrence of cracking even after being stored under a high temperature and high humidity condition. In addition, the gas barrier films of the present invention have an effect of decreasing the occurrence of dark spots as they are used as a sealing film for an organic EL device.

Incidentally, the present application is based upon the prior Japanese Patent Application No. 2013-164209, filed on Aug. 7, 2013, the entire contents of which are incorporated herein by reference.

1. A gas barrier film comprising a plurality of gas barrier layers, the gas barrier film being obtained by coating a coating liquid containing a polysilazane compound on a substrate by simultaneous multilayer coating and drying it to form a plurality of coating layers and then irradiating the plurality of coating layers with vacuum ultraviolet rays from the side of the farthest coating layer from the substrate to conduct a modification treatment,
wherein at least one layer of the gas barrier layers contains at least one kind of element (however, silicon and carbon are excluded) selected from the group consisting of elements of group 2, group 13, and group 14 in the long form of the periodic table.

2. The gas barrier film according to claim 1, wherein at least one kind of element selected from the group consisting of elements of group 2, group 13, and group 14 in the long form of the periodic table is at least one kind selected from the group consisting of aluminum, indium, gallium, magnesium, calcium, germanium, and boron.

3. The gas barrier film according to claim 1, wherein a thickness of the substrate is from 10 to 100 μm.

4. The gas barrier film according to claim 1, wherein the gas barrier film is formed by further conducting a temperature treatment after the modification treatment.

5. A method for producing a gas barrier film including a plurality of gas barrier layers, the method comprising:
a step of forming a plurality of coating layers by coating a coating liquid containing a polysilazane compound on a substrate by simultaneous multilayer coating and drying it; and
a step of conducting a modification treatment by irradiating the plurality of coating layers with vacuum ultraviolet rays from the side of the farthest coating layer from the substrate,
wherein at least one layer of the coating layers contains at least one kind of element (however, silicon and carbon are excluded) selected from the group consisting of elements of group 2, group 13, and group 14 in the long form of the periodic table.

6. An electronic device comprising:
an electronic device body; and
the gas barrier film according to claim 1.
